(19) United States
(12) Patent Application Publication
(10) Pub. No.: US 2010/0176396 A1
(43) Pub. Date: Jul. 15, 2010

(54) PROBE, PROBE CARD, AND METHOD OF PRODUCTION OF PROBE

(75) Inventor: Koichi Wada, Tokyo (JP)

Correspondence Address: GREENBLUM & BERNSTEIN, P.L.C., 1950 ROLAND CLARKE PLACE, RESTON, VA, 20191, US

(73) Assignee: ADVANTEST CORPORATION, Tokyo (JP)

(21) Appl. No.: 12/667,071

(22) PCT Filed: Jul. 3, 2007
(86) PCT No.: PCT/JP2007/063313

§ 371 Date: Mar. 1, 2010

(51) Int. Cl. H01L 23/498; H01L 21/28; H01L 21/3065

(52) U.S. Cl. 257/48; 438/613; 438/710; 257/E21.218; 257/E21.158; 257/E23.06

(57) ABSTRACT

A probe comprises: a beam part having a Si layer composed of monocrystalline silicon; an interconnect part provided along the longitudinal direction of the beam part on one main surface of the beam part; a contact part provided at a front end part of the interconnect part and to be electrically connected to input/output terminals of an IC device; and a base part supporting a plurality of beam parts all together in a cantilever fashion, and a longitudinal direction of the beam part substantially matches with a crystal orientation <100> of monocrystalline silicon of the Si layer.

### TECHNICAL FIELD

The present invention relates to a probe for contacting pads or electrodes or leads or other such input/output terminals provided at integrated circuits and other electrical circuits formed on a semiconductor wafer, a semiconductor chip, a semiconductor device package, a printed circuit board, etc. (hereinafter also referred to representatively as “IC devices”) for establishing electrical contact with the IC devices when testing IC devices, to a probe card comprising the same, and to a method of production of the probe.

### BACKGROUND ART

A large number of semiconductor integrated circuit devices are built into a silicon wafer etc., then processed by dicing, bonding, packaging, and other steps to complete electronic devices. Such IC devices are subjected to operational tests before shipment. These tests are run in the wafer state or the state of the completed products.

At the time of testing an IC device in a wafer state, as the probe for establishing electrical connection with the IC device under test, one having a base part fixed on a board, beam parts with back end sides provided at the base part and with front end sides projecting from the base part, and conductive parts formed on the surface of the beam parts (hereinafter also simply referred to as a “silicon finger contactor”) has been known in the past (for example, see Patent Citations 1 to 3).

This silicon finger contactor is formed from a silicon wafer using photolithography or another semiconductor production technology, so it becomes relatively easier to handle the reduction in size and pitch of input/output terminals accompanying the reduction in size of IC devices under test. However, IC devices are continuously being reduced in size, so further fineness of the silicon finger contactor is desired.

As opposed to this, if simply shortening a silicon finger contactor, the beam parts will become harder and flexing when contacting the input/output terminals of an IC device will become more difficult. For this reason, the silicon finger contactor becomes easier to break and the fatigue resistance characteristics deteriorate.

[Patent Citation 1] Japanese Patent Publication (A) No. 2000-249722

[Patent Citation 2] Japanese Patent Publication (A) No. 2001-159642

[Patent Citation 3] WO 03/071289 pamphlet

### DISCLOSURE OF THE INVENTION

### Technical Problem

The problem which the present invention attempts to solve is to provide a probe superior in fatigue resistance characteristics, a probe card comprising the same, and a method of production of the probe card.

### Solution to Problem

To achieve the above object, according to a first aspect of the present invention, there is provided a probe for contacting an input/output terminal of a device under test for establishing an electrical connection between the device under test and a test system when testing the device under test, characterized in that the probe at least comprises: a beam part having a Si layer composed of monocrystalline silicon; and a conductive part provided on one main surface of the beam part along a longitudinal direction of the beam part and to be electrically connected with the input/output terminal of the device under test, and the longitudinal direction of the beam part substantially matches with a crystal orientation <100> of monocrystalline silicon of the Si layer (see claim 1).

While the present invention is not particularly limited to this, preferably the probe further comprises a base part supporting a plurality of the beam parts all together in a cantilever fashion (see claim 2).

While the present invention is not particularly limited to this, preferably the conductive part has: an interconnect part provided on the one main surface of the beam part along the longitudinal direction; and a contact part provided at a front end of the interconnect part and contacting the input/output terminal of the device under test (see claim 3).

To achieve the above object, according to a second aspect of the present invention, there is provided a probe card characterized in that the probe card comprises: the above-mentioned probe; and a board to which the base part of the probe is fixed (see claim 4).

To achieve the above object, according to a third aspect of the present invention, there is provided a method of production of the above-mentioned probe, the method of production of a probe characterized by comprising: forming a resist layer on a surface of a silicon wafer; and etching the silicon wafer to form the beam part (see claim 5).

While the present invention is not particularly limited to this, preferably the silicon wafer has a main surface of a surface orientation {100} and is given an orientation flat or notch showing a crystal orientation <100> (see claim 6).

Here, the “surface orientation {100}” includes the (100) surface and all surfaces equivalent to it. Specifically, it includes the (100), (010), (001), (1*00), (01*0), and (001*) surfaces. Further, the “crystal orientation <100>” includes the crystal orientation [100] and all orientations equivalent to it. Specifically, it includes [100], [010], [001], [1*00], [01*0], and [001*].

Note that, in this Description, for example, when expressing

(h k̅1) [Formula 1]

it is abbreviated as (hk*1). Similarly, in this Description, for example, when expressing

[h k̅1] [Formula 2]

it is abbreviated as [hk*1].

While the present invention is not particularly limited to this, preferably the silicon wafer has a main surface of a surface orientation {100} and is given an orientation flat or notch showing a crystal orientation <110>, and the method of production of the probe comprises: forming the resist layer on the surface of the silicon wafer in the state that the silicon wafer is rotated by substantially 45 degree from a usual state so that a longitudinal direction of the beam part is substantially matched with a crystal orientation <100> of the silicon wafer (see claim 7).

While the present invention is not particularly limited to this, preferably the silicon wafer has a main surface of a surface orientation {100} and is given an orientation flat or notch showing a crystal orientation <110>, and the method of production of the probe comprises: forming a pattern for forming the resist layer on a mask in the state that the pattern is rotated by substantially 45 degree from a usual state; and forming the resist layer on the surface of the silicon wafer using the mask so that a longitudinal direction of the beam part is substantially matched with a crystal orientation <100> of the silicon wafer (see claim 8).

While the present invention is not particularly limited to this, preferably the silicon wafer has a main surface of a surface orientation {100} and is given an orientation flat or notch showing a crystal orientation <110>, and the method of production of the probe comprises: forming the resist layer on the surface of the silicon wafer in the state that a mask for forming the resist layer is rotated by substantially 45 degree from a usual state so that a longitudinal direction of the beam part is substantially matched with a crystal orientation <100> of the silicon wafer (see claim 9).

Note that, in the present invention, the “usual state” means the state that a silicon wafer having a main surface of a surface orientation {100} surface and given an orientation flat or notch showing the crystal orientation <110> is used and a longitudinal direction of the beam part is substantially matched with the crystal orientation <110> of the silicon wafer.

While the present invention is not particularly limited to this, preferably the method of production of the probe comprises etching the silicon wafer by using a DRIE (deep reactive ion etching) method (see claim 10).

### ADVANTAGEOUS EFFECTS OF INVENTION

In the present invention, a longitudinal direction of a beam part of a probe is substantially matched with a crystal orientation of the lowest Young's modulus, that is, the crystal orientation <100>, so for example compared with when matching a longitudinal direction of the beam part with the crystal orientation <110>, it will not become harder and the probe will suitably flex when contacting input/output terminals of the device under test even if the probe is shortened. For this reason, the probe becomes harder to break and the fatigue resistance characteristics are improved.

### BRIEF DESCRIPTION OF DRAWINGS

FIG. 1 is a schematic view showing an electronic device test system in a first embodiment of the present invention.

FIG. 2 is a schematic view showing the connection relationship among a test head, probe card, and prober in the first embodiment of the present invention.

FIG. 3 is a schematic cross-sectional view of the probe card in the first embodiment of the present invention.

FIG. 4 is a partial plan view of the probe card seen from the bottom in the first embodiment of the present invention.

FIG. 5 is a partial plan view of a probe in the first embodiment of the present invention.

FIG. 6A is a cross-sectional view along the line VIA-VIA of FIG. 5.

FIG. 6B is a cross-sectional view along the line VIB-VIB of FIG. 5.

FIG. 7A is a plan view seen from the top of an SOI wafer at a first step of a method of production of a probe according to the first embodiment of the present invention.

FIG. 7B is a cross-sectional view along the line VIIB-VIIB of FIG. 7A.

FIG. 8A is a partial plan view seen from the bottom of an SOI wafer at a second step of the method of production of a probe according to the first embodiment of the present invention.

FIG. 8B is a cross-sectional view along the line VIIIB-VIIIB of FIG. 8A.

FIG. 9 is a cross-sectional view of an SOI wafer at a third step of the method of production of a probe according to the first embodiment of the present invention.

FIG. 10 is a cross-sectional view of an SOI wafer at a fourth step of the method of production of a probe according to the first embodiment of the present invention.

FIG. 11A is a plan view seen from the top of an SOI wafer at a fifth step of the method of production of a probe according to the first embodiment of the present invention.

FIG. 11B is an enlarged view of a part XIB of FIG. 11A.

FIG. 11C is a cross-sectional view along the line XIC-XIC of FIG. 11B.

FIG. 12 is a plan view seen from the top of an SOI wafer at a fifth step of a method of production of a probe according to a second embodiment of the present invention.

FIG. 13A is a plan view of a photomask used at a fifth step of a method of production of a probe according to a third embodiment of the present invention.

FIG. 13B is a plan view seen from the top of an SOI wafer at a fifth step of the method of production of a probe according to a fourth embodiment of the present invention.

FIG. 14 is a cross-sectional view of an SOI wafer at a sixth step of the method of production of a probe according to the first embodiment of the present invention.

FIG. 15A is a plan view seen from the top of an SOI wafer at a seventh step of the method of production of a probe according to the first embodiment of the present invention.

FIG. 15B is an enlarged view of a part XVB of FIG. 15A.

FIG. 15C is a cross-sectional view along the line XVC-XVC of FIG. 15B.

FIG. 16 is a cross-sectional view of an SOI wafer at an eighth step of the method of production of a probe according to the first embodiment of the present invention.

FIG. 17 is a cross-sectional view of an SOI wafer at a ninth step of the method of production of a probe according to the first embodiment of the present invention.

FIG. 18 is a cross-sectional view of an SOI wafer at a 10th step of the method of production of a probe according to the first embodiment of the present invention.

FIG. 19 is a cross-sectional view of an SOI wafer at an 11th step of the method of production of a probe according to the first embodiment of the present invention.

FIG. 20A is a plan view seen from the top of an SOI wafer at a 12th step of the method of production of a probe according to the first embodiment of the present invention.

FIG. 20B is a cross-sectional view along the line XXB-XXB of FIG. 20A.

FIG. 21 is a cross-sectional view of an SOI wafer at a 13th step of the method of production of a probe according to the first embodiment of the present invention.

FIG. 22A is a plan view seen from the top of an SOI wafer at a 14th step of the method of production of a probe according to the first embodiment of the present invention.

FIG. 22B is a cross-sectional view along the line XXIIB-XXIIB of FIG. 22A.

FIG. 23 is a cross-sectional view of an SOI wafer at a 15th step of the method of production of a probe according to the first embodiment of the present invention.

FIG. 24A is a plan view seen from the top of an SOI wafer at a 16th step of the method of production of a probe according to the first embodiment of the present invention.

FIG. 24B is a cross-sectional view along the line XXIVB-XXIVB of FIG. 24A.

FIG. 25A is a plan view seen from the top of an SOI wafer at a 17th step of the method of production of a probe according to the first embodiment of the present invention.

FIG. 25B is a cross-sectional view along the line XXVB-XXVB of FIG. 25A.

FIG. 26 is a cross-sectional view of an SOI wafer at an 18th step of the method of production of a probe according to the first embodiment of the present invention.

FIG. 27A is a plan view seen from the top of an SOI wafer at a 19th step of the method of production of a probe according to the first embodiment of the present invention.

FIG. 27B is a cross-sectional view along the line XXVIIB-XXVIIB of FIG. 27A.

FIG. 28A is a plan view seen from the top of an SOI wafer at a 20th step of the method of production of a probe according to the first embodiment of the present invention.

FIG. 28B is a cross-sectional view along the line XXVIIIB-XXVIIIB of FIG. 28A.

FIG. 29 is a cross-sectional view of an SOI wafer at a 21st step of the method of production of a probe according to the first embodiment of the present invention.

FIG. 30 is a cross-sectional view of an SOI wafer at a 22nd step of the method of production of a probe according to the first embodiment of the present invention.

FIG. 31A is a plan view seen from the top of an SOI wafer at a 23rd step of the method of production of a probe according to the first embodiment of the present invention.

FIG. 31B is a cross-sectional view along the line XXXIB-XXXIB of FIG. 31A.

FIG. 32 is a cross-sectional view of an SOI wafer at a 24th step of the method of production of a probe according to the first embodiment of the present invention.

FIG. 33A is a plan view seen from the top of an SOI wafer at a 25th step of the method of production of a probe according to the first embodiment of the present invention.

FIG. 33B is an enlarged view of a part XXXIIIB of FIG. 33A.

FIG. 33C is a cross-sectional view along the line XXXIIIC-XXXIIIC of FIG. 33B.

FIG. 34 is a cross-sectional view of an SOI wafer at a 26th step of the method of production of a probe according to the first embodiment of the present invention.

FIG. 35A is a plan view seen from the top of an SOI wafer at a 27th step of the method of production of a probe according to the first embodiment of the present invention.

FIG. 35B is an enlarged view of a part XXXVB of FIG. 35A.

FIG. 35C is a cross-sectional view along the line XXXVC-XXXVC of FIG. 35B.

FIG. 36 is a cross-sectional view of an SOI wafer at a 28th step of the method of production of a probe according to the first embodiment of the present invention.

FIG. 37 is a cross-sectional view of an SOI wafer at a 29th step of the method of production of a probe according to the first embodiment of the present invention.

FIG. 38A is a plan view seen from the bottom of an SOI wafer at a 30th step of the method of production of a probe according to the first embodiment of the present invention.

FIG. 38B is a cross-sectional view along the line XXXVIIIB-XXXVIIIB of FIG. 38A.

FIG. 39 is a cross-sectional view of an SOI wafer at a 31st step of the method of production of a probe according to the first embodiment of the present invention.

FIG. 40 is a cross-sectional view of an SOI wafer at a 32nd step of the method of production of a probe according to the first embodiment of the present invention.

FIG. 41 is a cross-sectional view of a prober at a 33rd step of the method of a probe according to the first embodiment of the present invention.

FIG. 42 is a cross-sectional view of a prober at a 34th step of the method of a probe according to the first embodiment of the present invention.

### EXPLANATION OF REFERENCES

1 . . . electronic device test system
10 . . . test head
20 . . . interface section
30 . . . probe card
31 . . . probe board
40 . . . probe
41 . . . base part
42 . . . beam part
422 . . . rear end region
43A to 43C . . . grooves
44 . . . interconnect part
45 . . . contact part
46 . . . SOI wafer
46a . . . main surface of surface orientation (100)
46b . . . orientation flat showing crystal orientation <100>
100 . . . semiconductor wafer under test
110 . . . input/output terminals

### BEST MODE FOR CARRYING OUT THE INVENTION

Below, embodiments of the present invention will be explained based on the drawings.

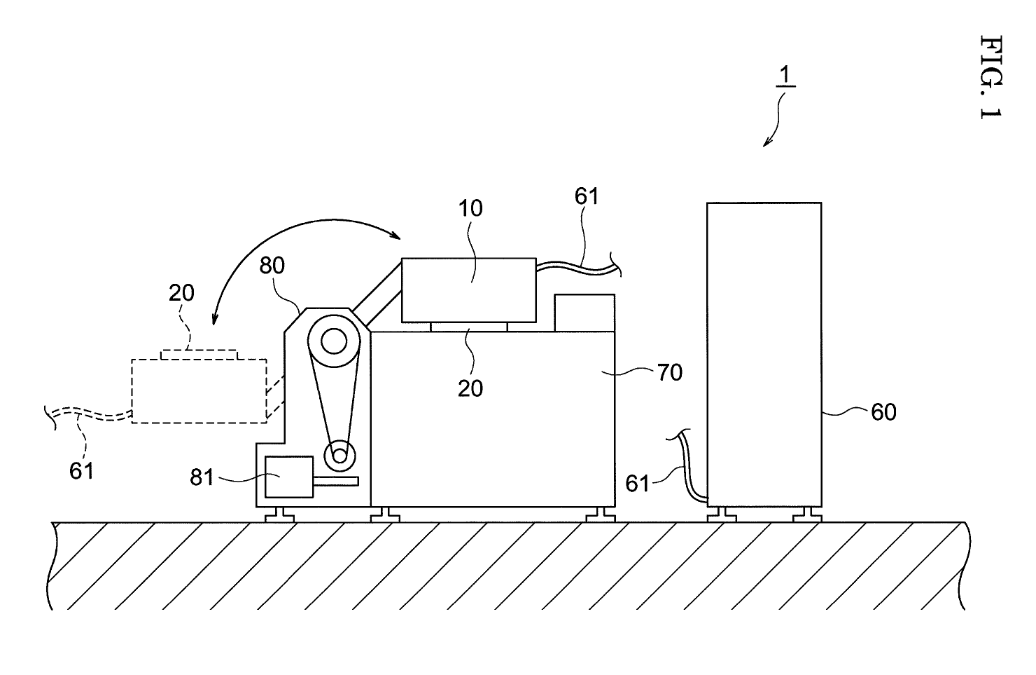

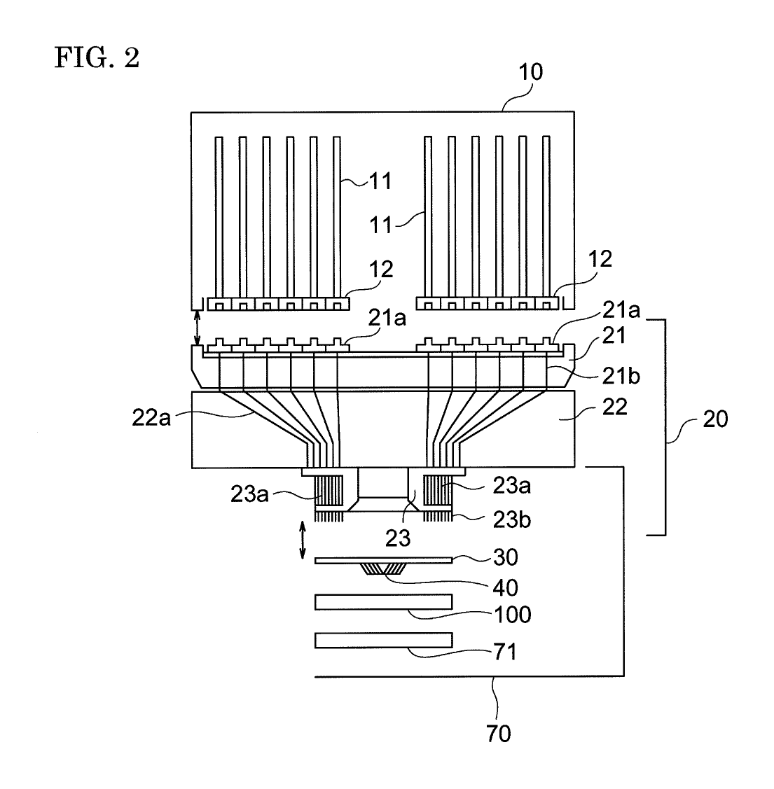

FIG. 1 is a schematic view showing an electronic device test system of a first embodiment of the present invention, while FIG. 2 is a conceptual view showing the connection relationships of a test head, probe card, and prober in a first embodiment of the present invention.

The electronic device test system 1 in the first embodiment of the present invention, as shown in FIG. 1, comprises a test head 10, a tester 60, and a prober 70. The tester 60 is electrically connected through a cable bundle 61 to the test head 10 and can input and output test signals with IC devices built into a silicon wafer 100 under test. The test head 10 is arranged above the prober 70 by a manipulator 80 and a drive motor 81.

As shown in FIG. 1 and FIG. 2, a large number of pin electronics 11 are provided inside the test head 10. These pin electronics 11 are connected through the cable bundle 61 having several hundred internal cables to the tester 60. Further, the pin electronics 11 are electrically connected to connectors 12 for connection with a mother board 21 and therefore can be electrically connected with contact terminals 21a on the mother board 21 of the interface section 20.

The test head 10 and the prober 70 are connected through the interface section 20. This interface section 20 comprises the mother board 21, a wafer performance board 22, and a frog ring 23. The mother board 21 is provided with the contact terminals 21a for electrical connection with the connectors 12 on the test head 10 side. Interconnect patterns 21b are formed for electrically connecting the contact terminals 21a and the wafer performance board 22. The wafer performance board 22 is electrically connected through pogo pins etc. to the mother board 21. Interconnect patterns 22a are formed so as to convert the pitch of the interconnect patterns 21b on the mother board 21 to the frog ring 23 side pitch in order to electrically connect the interconnect patterns 21b to a flexible board 23a provided in the frog ring 23.

The frog ring 23 is provided on the wafer performance board 22. To allow some alignment between the test head 10 and the prober 70, an internal transmission path is formed by the flexible board 23a. A large number of pogo pins 23b to which this flexible board 23a is electrically connected are mounted at the bottom surface of the frog ring 23.

The probe card 30 on the bottom surface of which a large number of probes 40 are mounted is electrically connected through the pogo pins 23b to the frog ring 23. While not particularly illustrated, the probe card 30 is fixed through a holder to a top plate of the prober 70. The probes 40 approach the inside of the probe 70 through an opening in the top plate.

The prober 70 can hold a wafer under test 100 on a chuck 71 by suction etc. and automatically supply that wafer 100 to a position facing the probe card 30.

In the above such configuration of an electronic device test system 1, the wafer under test 100 held on the chuck 71 is pushed by the prober 70 against the probe card 30 to make the probes 40 electrically contact the input/output terminals 110 of an IC device built in the wafer under test 100. In that state, the tester 60 sends the IC device a DC signal and a digital signal and receives an output signal from the IC device. The output signal (response signal) from this IC device is compared with the expected values by the tester 60 to evaluate the electrical characteristics of the IC device.

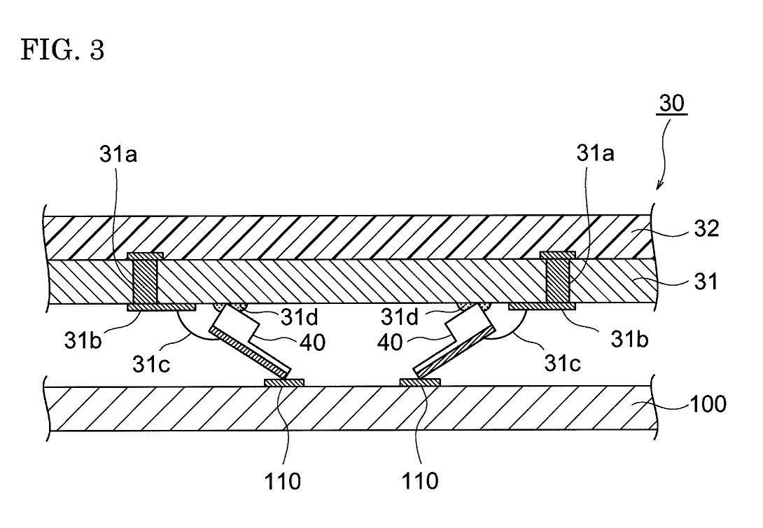

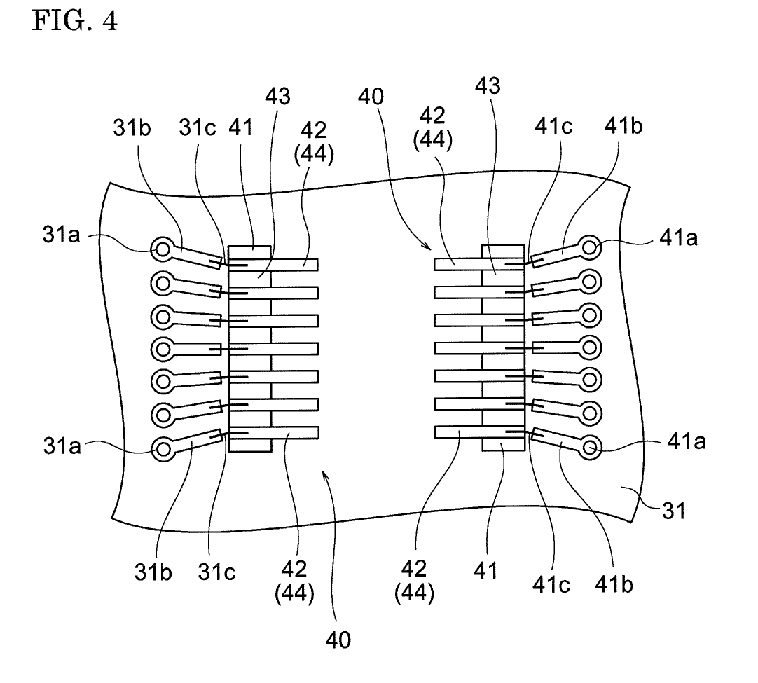

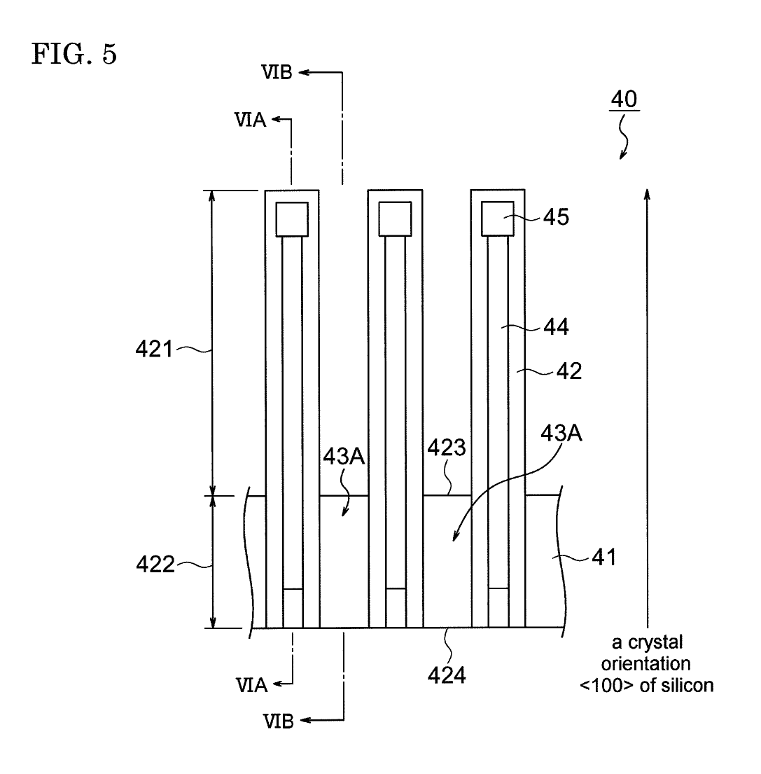

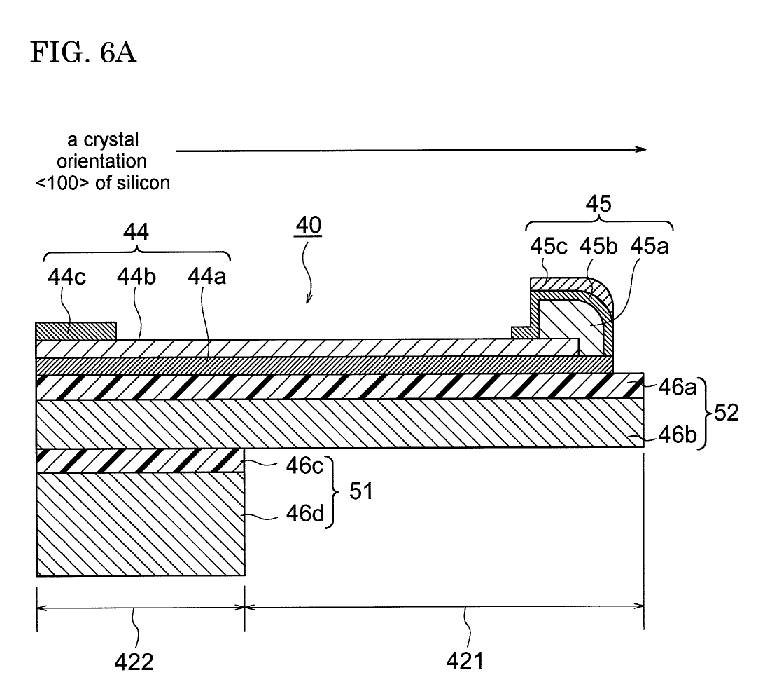

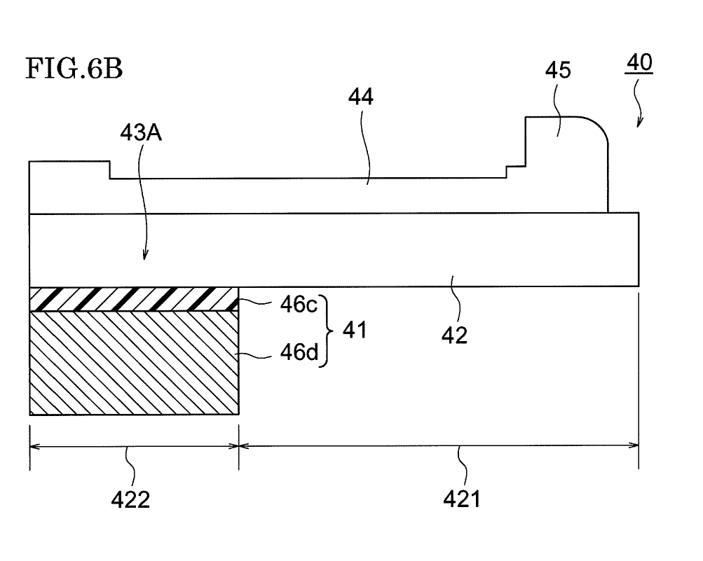

FIG. 3 is a schematic cross-sectional view of a probe card in a first embodiment of the present invention, FIG. 4 is a partial plan view of a probe card in a first embodiment of the present invention seen from the bottom side, FIG. 5 is a partial plan view of a probe in a first embodiment of the present invention, FIG. 6A is a cross-sectional view along the line VIA-VIA of FIG. 5, and FIG. 6B is a cross-sectional view along the line VIB-VIB of FIG. 5.

The probe card 30 in the embodiment, as shown in FIG. 3 and FIG. 4, comprises: a probe board 31 comprising for example a multilayer circuit board etc.; a stiffener 32 attached to a top surface of the probe board 31 for reinforcing the mechanical strength; and a large number of silicon finger contactors 40 mounted on the bottom surface of the probe board 31.

The probe board 31 is formed with through holes 31a so as to pass from the bottom surface to the top surface. Connection traces 31b connected to the through holes 31a are formed on the bottom surface.

The silicon finger contactors (probes) 40 in the present embodiment are probes for contacting the input/output terminals 110 of an IC device for establishing electrical connection between the IC device and the test head 10 at the time of test of the IC device.

Each probe 40, as shown in FIG. 5 to FIG. 6B, comprises: a base part 41 fixed to a probe board 31; columnar beam parts 42 supported at back end sides by the base part 41 and with front end sides sticking out from the base part 41; interconnect parts 44 formed on the top surfaces of the beam parts 42; and contact parts 45 formed at front ends of the interconnect parts 44.

Note that, in the present embodiment, the “back end side” in each probe 40 indicates the side fixed to the probe board 31 (left side in FIG. 6A). As opposed to this, the “front end side” in the probe 40 indicates the side contacting the input/output terminals 110 of the semiconductor wafer under test 100 (right side in FIG. 6A). Further, a region of the beam parts 42 sticking out from the base part 41 toward the front end side is called a projecting region 421, while a region of the beam parts 42 supported by the base part 41 is called a rear end region 422.

The base part 41 and beam parts 42 of each probe 40 are produced by applying photolithography or other semiconductor production technology to the silicon wafer 46. As shown in FIG. 5 to FIG. 6B, a single base part 41 supports a plurality of beam parts 42 together at the rear end region 422 in a cantilever fashion. That plurality of beam parts 42 stick out from the base part 41 along directions substantially parallel to each other in a finger shape (comb shape).

The base part 41, as shown in FIG. 6A, comprises: a support layer 46d made of silicon; and a BOX layer 46c formed on this support layer 46d and made of silicon oxide (SiO₂). On the other hand, each beam part 42 comprises: an active layer 46b made of silicon (Si); and a first SiO₂ layer 46a formed on that active layer 46b and functioning as an insulating layer.

Further, in the present embodiment, as shown in FIG. 5 to FIG. 6B, the longitudinal direction of each beam part 42 substantially matches with a crystal orientation <100> of monocrystalline silicon forming the active layer 46b. In general, there is a strong anisotropy in the Young's modulus (the longitudinal elastic modulus) of monocrystalline silicone. Specifically, the Young's modulus of the crystal orientation <100> is about 130 [GPa], the Young's modulus of the crystal orientation <110> is about 170 [GPa], and the Young's modulus of the crystal orientation <111> is about 190 [GPa]. In the present embodiment, the longitudinal direction of the probe 30 is substantially matched with the crystal orientation <100> where the Young's modulus is the smallest. Due to this, it will not become harder and the probe will suitably flex when contacting input/output terminals of the device under test even if shortening the probe 40. For this reason, the probe becomes harder to break and the fatigue resistance characteristics are improved.

Note that, in the past, due to the orientation of the orientation flats of generally available silicon wafers, the longitudinal direction of a probe matches with the crystal orientation <110>. As opposed to this, by matching the longitudinal direction of the beam part 42 with the crystal orientation <100> like in the present embodiment, the Young's modulus is reduced from about 170 [GPa] to about 130 [GPa], so it is possible to shorten the beam part 42 compared with a conventional probe. On the other hand, it is necessary to apply a certain load or more to the probe in order to maintain the stability of the contact with the input/output terminals of the IC device. And it is necessary to keep the tensile stress generated at a beam part down to a predetermined amount or less in order to secure sufficient fatigue resistance characteristics. In the present embodiment, for example, when shortening the beam part 42 by 16% compared with a conventional probe, the above condition can be met by reducing the thickness of the beam part 42 by 8% on the basis of the relationship of the following two formulas. In the following two formulas, E is the Young's modulus, t is the thickness, and 1 is the length.

$$\begin{matrix}Load \text{:} F ∝ E \frac{{t}^{3}}{{l}^{3}} & [ Formula 3 ] \\ Stress \text{:} σ ∝ E \frac{t}{{l}^{2}} & [ Formula 4 ]\end{matrix}$$

As shown in FIG. 5 to FIG. 6B, grooves 43A are provided between adjoining beam parts 42 in the rear end region 421 of the plurality of beam parts 42. As will be understood if comparing FIG. 6A and FIG. 6B, each groove 43A has a depth corresponding to the thicknesses of the first SiO₂ layer 46a and active layer 46b and has a width substantially the same as the width between the projecting region 421 of the beam parts 42.

As shown in FIG. 6A, an interconnect part 44 is provided on the insulating layer (the first SiO₂ layer) 46a. The interconnect part 44, as shown in the figure, comprises: a seed layer (power feed layer) 44a made of titanium and gold; a first interconnect layer 44b provided on the seed layer 44a and made of gold; and a second interconnect layer 44c provided at a back end of the first interconnect layer 44b and made of high purity gold. Note that, the first interconnect layer 44b has a 5 to 10 μm thickness. If the thickness of the first interconnect layer 44b is less than 5 μm, heat is liable to be generated, while if it is more than 10 μm, warping is liable to occur.

The front end part of the first interconnect layer 44b is formed with a contact part 45, so the first interconnect layer 44b is required to have a relatively high mechanical strength. For this reason, as the material forming the first interconnect layer 44b, 99.9% or higher purity gold to which nickel, cobalt, or another different type of metal material is added in an amount of less than 0.1% is used. The Vicker's hardness of the first interconnect layer 44b rises to Hv130 to 200. As opposed to this, the second interconnect layer 44c can be bonded at a later step and is given a high conductivity by being made of a purity 99.999% or higher gold.

The contact part 45 is provided at the front end of the interconnect part 44 so as to project out upward. This contact part 45 comprises: a first contact layer 45a formed on a step consist of the seed layer 44a and the first interconnect layer 44b; a second contact layer 45b provided so as to envelop the first contact layer 45a and made of gold; and a third contact layer 45c provided so as to envelop the second contact layer 45b. As the material for forming the first contact layer 45a, nickel or nickel cobalt or another nickel alloy may be mentioned. Further, as the material for forming the third contact layer 45c, rhodium, platinum, ruthenium, palladium, iridium, or their alloys or other conductive materials having a high hardness and superior in corrosion resistance may be mentioned. By providing such a contact part 45 at the front end of the interconnect part 44, it is possible to eliminate direct contact of the relatively deformable first interconnect layer 44b with the input/output terminals 110 of the IC device.

The above such configuration of a probe 40, as shown in FIG. 3, is mounted on the probe board 31 so as to face the input/output terminals 110 of an IC device under test built in the semiconductor wafer 100. Note that, FIG. 2 shows only two probes 30, however in actuality several hundred to several thousand probes 40 are mounted on the probe board 31.

Each probe 40, as shown in FIG. 3, is fixed to the probe board 31 using a binder 31d in the state with an edge part of the base part 41 made to abut against the probe board 31. As this binder 31d, for example, a UV ray curing type binder, a temperature curing type binder, a thermoplastic binder, etc. may be mentioned.

Further, a bonding wire 31c connected to a connection trace 31b is connected to the second interconnect layer 44c of the interconnect part 44. The interconnect part 44 of the probe 40 and the connection trace 31b of the probe board 31 are electrically connected via this bonding wire 31c. Note that, instead of the bonding wire 31c, solder balls may also be used to electrically connect the interconnect part 44 and connection trace 31b.

Such a configuration of a probe card 30 is used to test an IC device by using the prober 70 to press a wafer under test 100 against the probe card 30 so that the probes 40 on the probe board 31 and the input/output terminals 110 of the wafer under test 100 electrically contact each other and, in that state, having the tester input and output test signals with the IC devices.

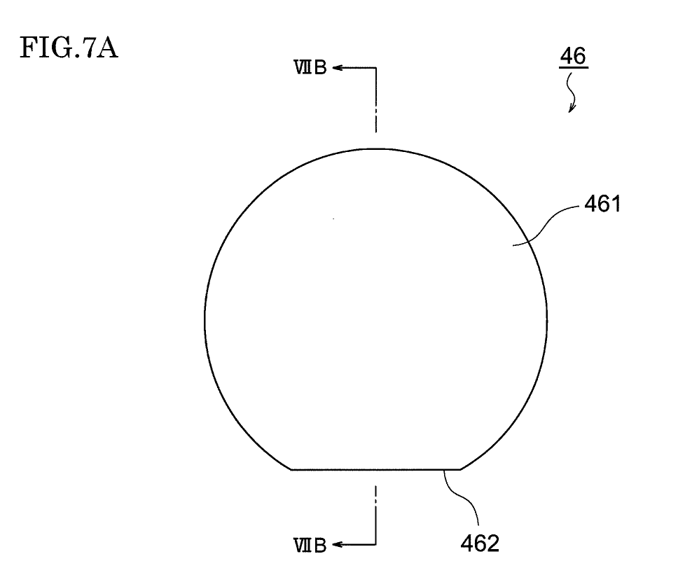

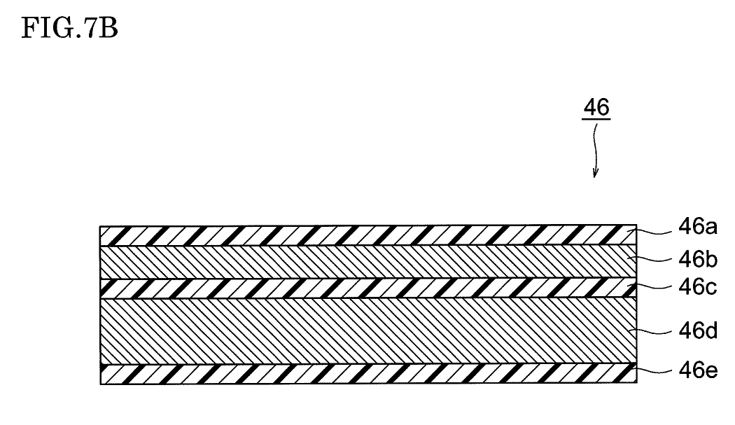

Below, an example of a method of production of a probe in an embodiment of the present invention will be explained with reference to FIG. 7A to FIG. 42. FIG. 7A to FIG. 42 are cross-sectional views or plan views of an SOI wafer at the different steps of the method of production of a probe according to the first embodiment of the present invention.

First, at a first step shown in FIG. 7A and FIG. 7B, an SOI wafer (silicon on insulator wafer) 46 is prepared. In the present embodiment, this SOI wafer 46, as shown in FIG. 7A, has a main surface 461 of the surface orientation (100) and is formed with an orientation flat 46b showing the crystal orientation <100>. Note that, instead of the orientation flat 46b, a notch showing the crystal orientation <100> may also be given to the SOI wafer 46.

This SOI wafer 46, as shown in FIG. 7B, comprises three SiO₂ layers 46a, 46c, and 46e among which two Si layers 46b, 46d are sandwiched. The SiO₂ layers 46a, 46c, and 46e of this SOI wafer 46 function as etching stoppers when producing the probes 40 and function as insulating layers.

Here, to make the high frequency characteristics of the probes 40 better, the first SiO₂ layer 46a has a 1 μm or higher layer thickness, while the active layer 46b has a 1 kΩ·cm or higher volume resistivity. Further, the tolerance of the layer thickness of the active layer 46b is ±3 μm or less and the tolerance of the layer thickness of the support layer 46d is ±1 μm or less so that the beam parts 42 have stable spring characteristics.

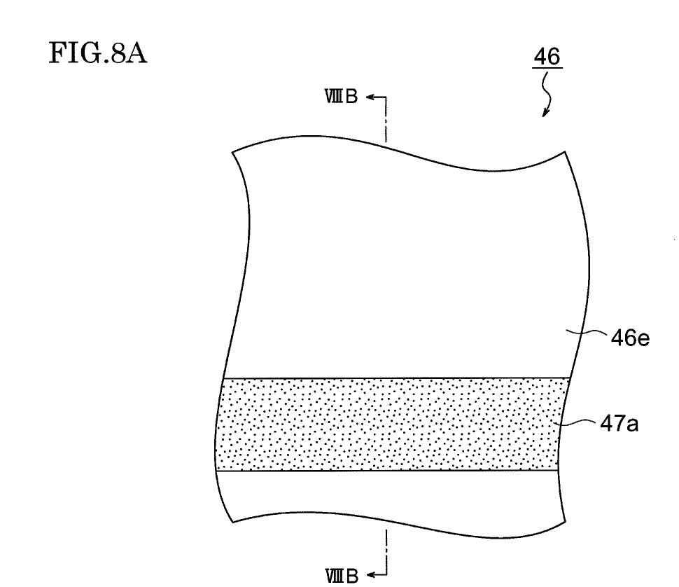

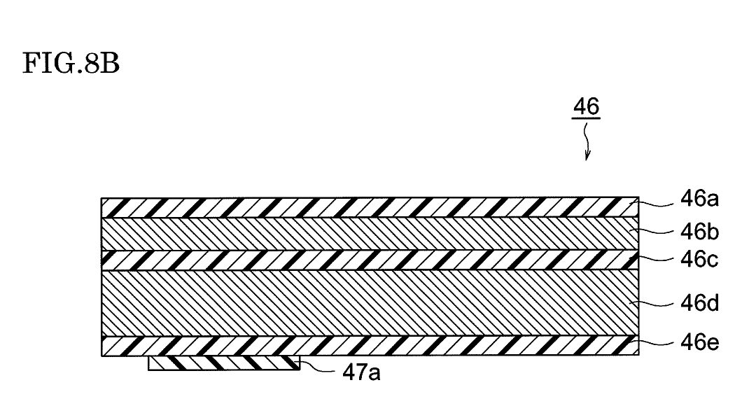

Next, at a second step shown in FIG. 8A and FIG. 8B, a first resist layer 47a is formed on the bottom surface of the SOI wafer 46. At this step, while not particularly illustrated, first a photoresist film is formed on the second SiO₂ 46e, then this photoresist film is overlaid with a photomask and exposed by UV rays to cure (solidify) it in that state so as to form the first resist layer 47a on a part of the second SiO₂ layer 46e. Note that the parts of the photoresist film not exposed by the UV rays are then dissolved and washed away from the second SiO₂ layer 46e. This first resist layer 47a functions as an etching mask pattern at the next third step.

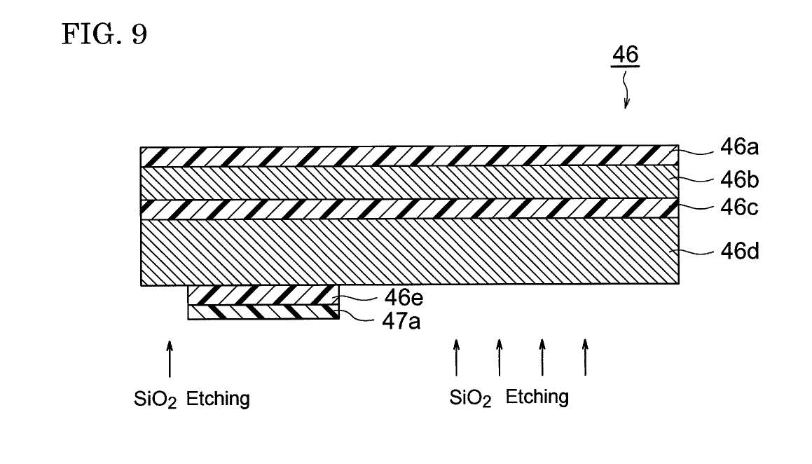

Next, at a third step shown in FIG. 9, for example RIE (reactive ion etching) etc. is used for etching the second SiO₂ layer 46e from the bottom of the SOI wafer 46. Due to this etching, the parts of the second SiO₂ layer 46e not protected by the first resist layer 47a are eaten away.

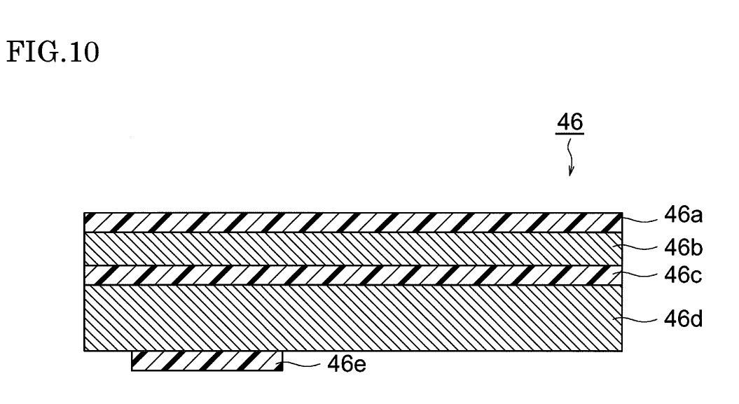

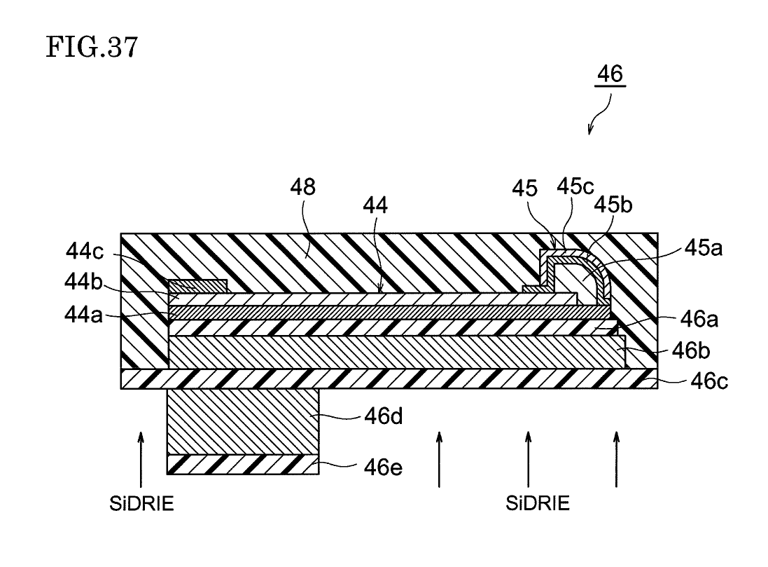

After this etching is completed, at a fourth step shown in FIG. 10, the first resist layer 47a remaining on the second SiO₂ layer 46e is removed (resist peeling). In this resist peeling, oxygen plasma is used for ashing the resist, then for example hydrogen persulfide or another washing solution is used to wash the SOI wafer 46. The second SiO₂ layer 46e remaining at the bottom of the SOI wafer 46 functions as a mask material in the etching at a 29th step explained in FIG. 37.

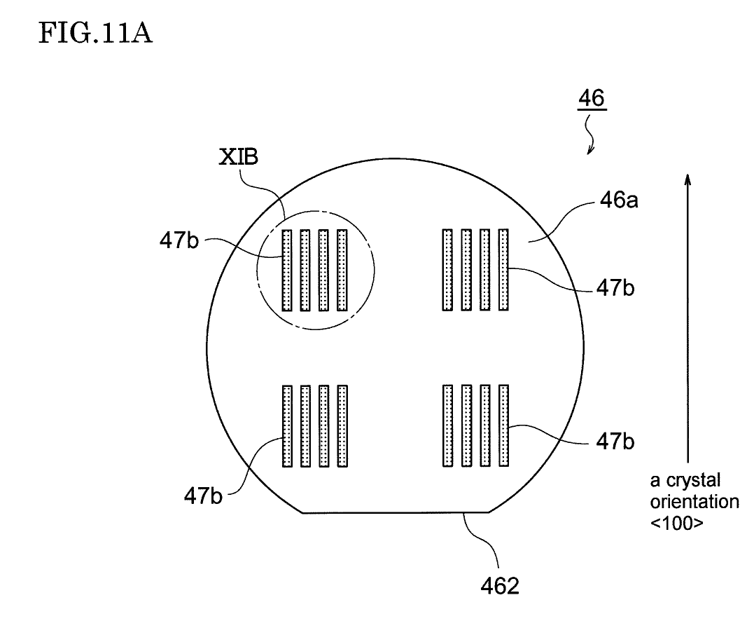

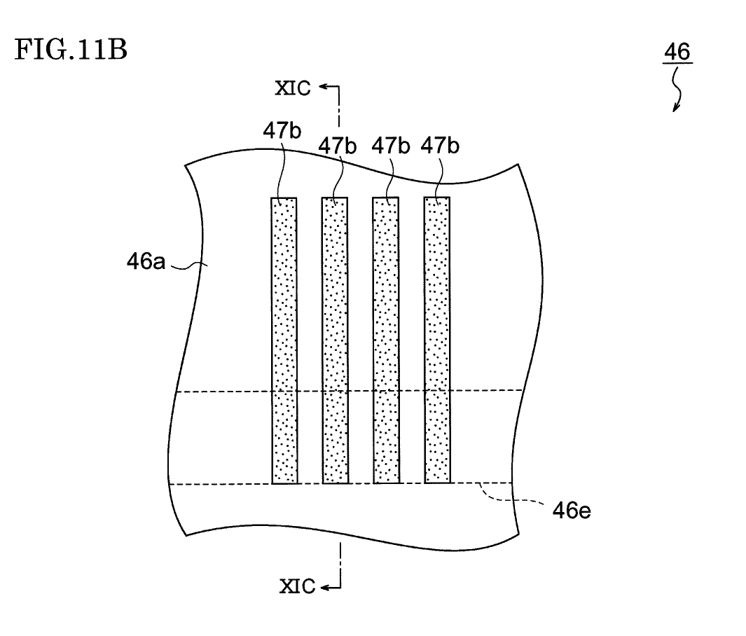

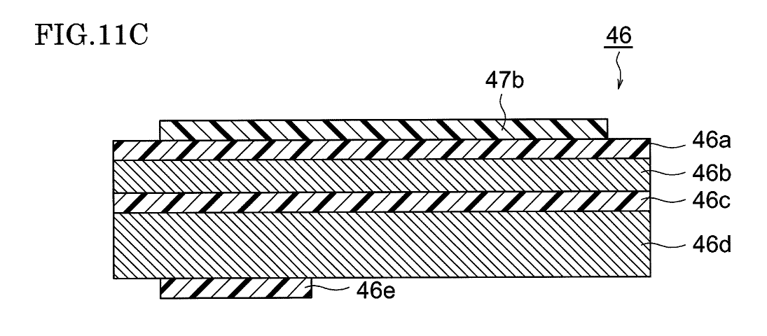

Next, at a fifth step shown in FIG. 11A to FIG. 11C, a second resist layer 47b is formed on the surface of the first SiO₂ layer 46a. As shown in FIG. 11A and FIG. 11B, this second resist layer 47b is formed in a plurality of strip shapes on the top surface of the SOI wafer 46 by a similar procedure as the first resist layer 47a explained at the second step. Note that, in the present embodiment, as shown in FIG. 11A, the longitudinal direction of each second resist layer 47b substantially matches with the crystal orientation <100>.

Note that, when using a silicon wafer 46′ having a main surface 463 of a surface orientation (100) and formed with an orientation flat 464 showing the crystal orientation <110> as the silicon wafer for manufacturing the probe 40, the following procedure may also be used to form the first resist layer 47a.

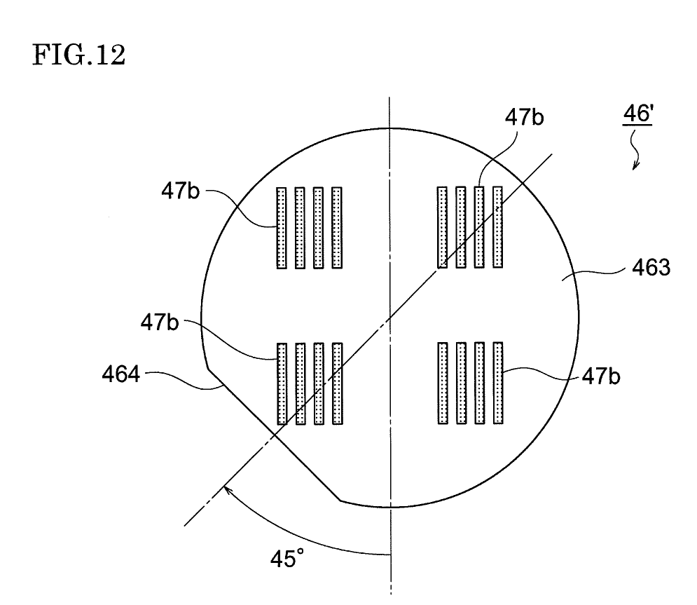

FIG. 12 is a plan view seen from the top of an SOI wafer at a fifth step of a method of production of a probe according to a second embodiment of the present invention. In the second embodiment of the present invention, as shown in FIG. 12, the silicon wafer 46′ is set in the exposure apparatus in the state that the silicon wafer 46′ is rotated by substantially 45 degree from a usual wafer set position, and the second resist layer 47b is formed on the silicon wafer 46′ in that state. Due to this, even if using the silicon wafer 46′ given an orientation flat 464 showing the crystal orientation <110>, the longitudinal direction of the second resist layer 47b can be easily matched with the crystal orientation <100>.

Note that, the “usual wafer set position” indicates the set position of a silicon wafer 46′ in an exposure apparatus when substantially matching a longitudinal direction of the beam part 42 with a crystal orientation <110> of the silicon wafer 46′. In the example shown in FIG. 12, the “usual wafer set position” is the state where the orientation flat 464 showing the crystal orientation <110> is positioned at the bottom in the figure.

Note that, it is also necessary to set the silicon wafer 46′ in the exposure apparatus in a state rotated by 45 degree similarly at the other steps for forming the resist layer (specifically, the second, eighth, 12th, 14th, 17th, 20th, and 25th steps).

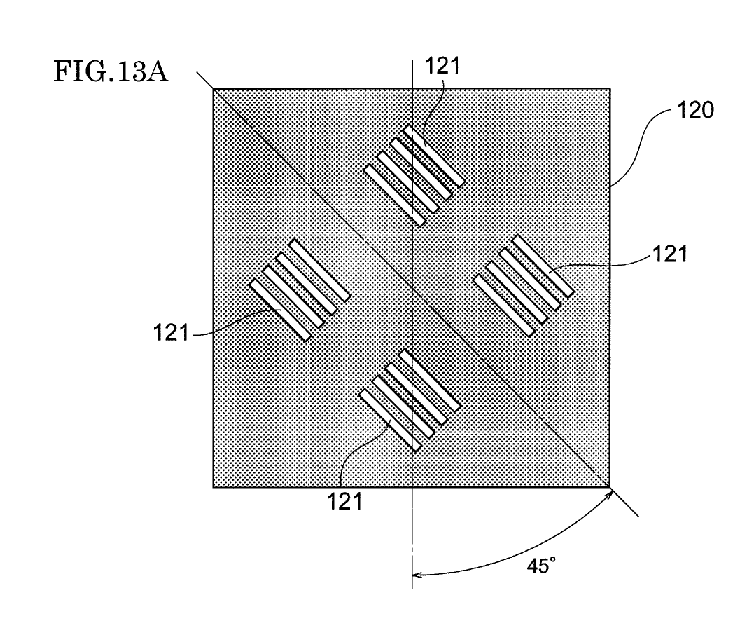

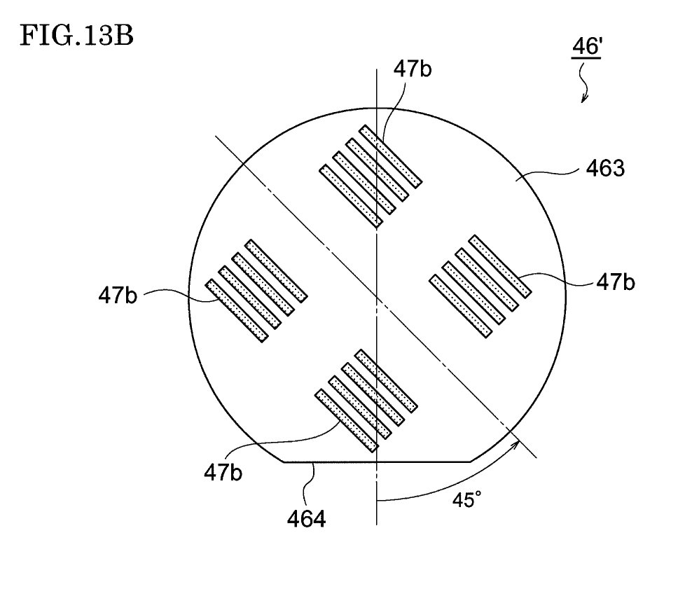

FIG. 13A is a plan view of a photomask used in a fifth step of a method of production of a probe according to a third embodiment of the present invention. In the third embodiment of the present invention, as shown in FIG. 13A, the pattern 121 (the transmissive portion) for forming the second resist layer 47b is formed on the photomask 120 in the state that the pattern 121 is rotated by substantially 45 degree from a usual pattern position. By using this photomask 120 to form the second resist layer 47b on the silicon wafer 46′, even if using a silicon wafer 46′ given an orientation flat 464 showing the crystal orientation <110>, it is possible to easily match the longitudinal direction of the second resist layer 47b with the crystal orientation <100>.

Note that, the “usual pattern position” indicates the position of a pattern with respect to the photomask when substantially matching a longitudinal direction of the beam part 42 with the crystal orientation <110> of the silicon wafer 46′. In the example shown in FIG. 13A, the “usual pattern position” is the state forming the pattern 121 on the photomask 120 with the longitudinal direction of the pattern 121 aligned with the vertical direction in the figure.

Note that it is also necessary to use photomasks formed with the pattern rotated by 45 degree similarly at the other steps for forming the resist layer (specifically, the second, eighth, 12th, 14th, 17th, 20th, and 25th steps).

FIG. 13B is a plan view seen from the top of an SOI wafer at a fifth step of the method of production of a probe according to a fourth embodiment of the present invention. In the fourth embodiment of the present invention, the photomask is formed at the usual pattern position, then, as shown in FIG. 13B, the photomask itself is rotated by 45 degree from a usual mask position, and the second resist layer 47b is formed on the silicon wafer 46′ in that state. Due to this, even if using a silicon wafer 46′ given an orientation flat 464 showing the crystal orientation <110>, it is possible to easily match the longitudinal direction of the second resist layer 47b with the crystal orientation <100>.

Note that, the “usual mask position” indicates the position of the photomask with respect to the silicon wafer 46′ when substantially matching the longitudinal direction of a beam part 42 with the crystal orientation <110> of the silicon wafer 46′. In the example shown in FIG. 13B, the “usual mask position” is the state forming the second resist layer 47b while matching the longitudinal direction of the second resist layer 47b with the vertical direction in the figure.

Note that it is also necessary to rotate the photomask by 45 degree similarly at the other steps for forming the resist layer (specifically, the second, eighth, 12th, 14th, 17th, 20th, and 25th steps).

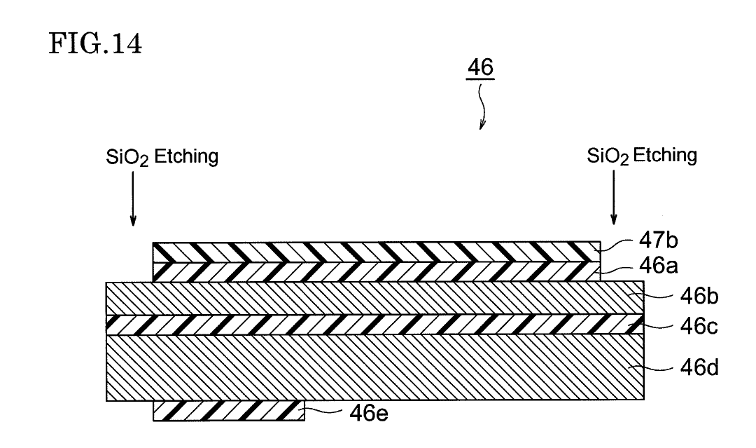

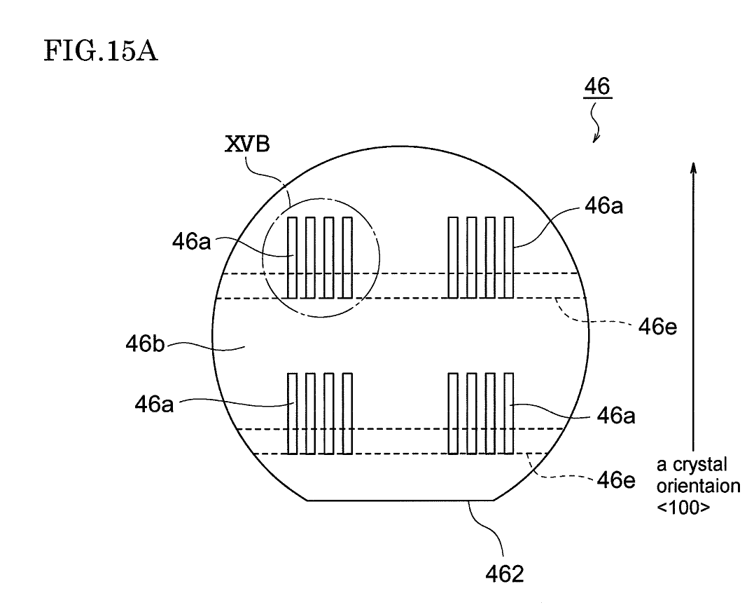

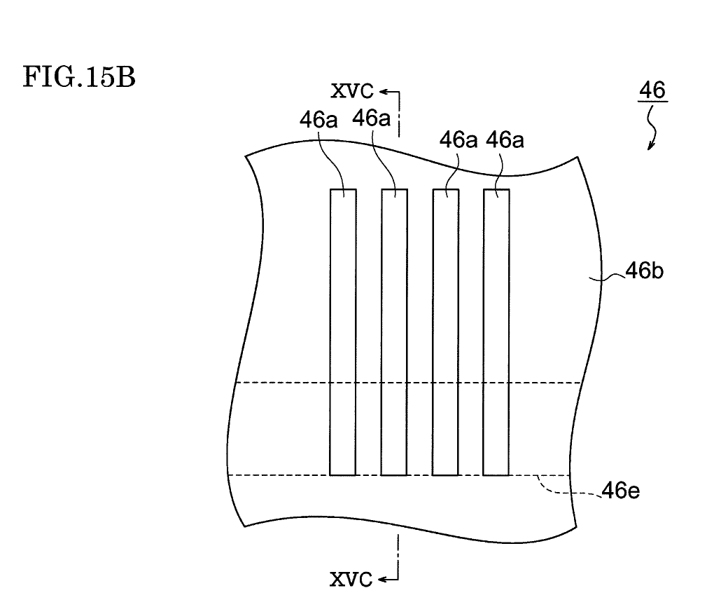

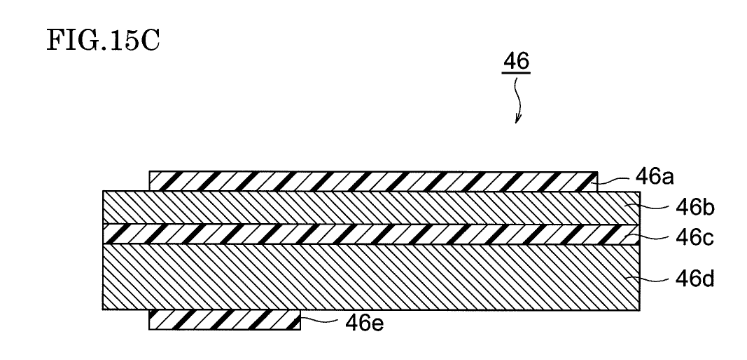

At a sixth step of the first embodiment of the present invention, as shown in FIG. 14, for example RIE etc. is used to etch the first SiO₂ layer 46a from above the SOI wafer 46. Due to this etching, the parts of the first SiO₂ layer 46a not protected by the second resist layer 47b are eaten away, and the first SiO₂ layer 46 becomes a plurality of strip shapes along the crystal orientation <100> (see FIG. 15A).

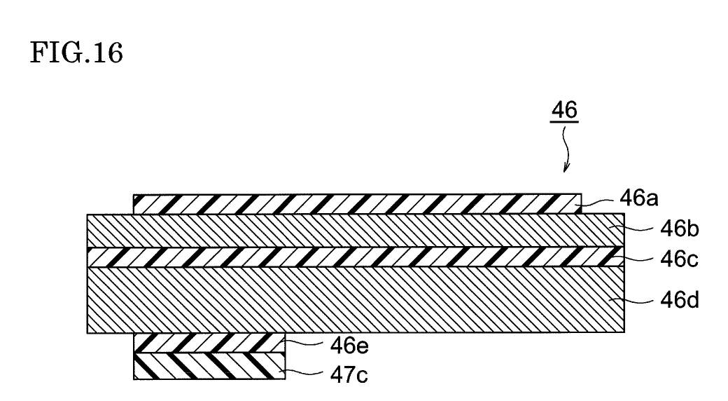

Next, at a seventh step shown in FIG. 15A to FIG. 15C, a similar procedure as with the above-mentioned fourth step is used to remove the second resist layer 47b. At an eighth step shown in FIG. 16, a similar procedure as with the above-mentioned second step is used to form a third resist layer 47c on the second SiO₂ layer 46e.

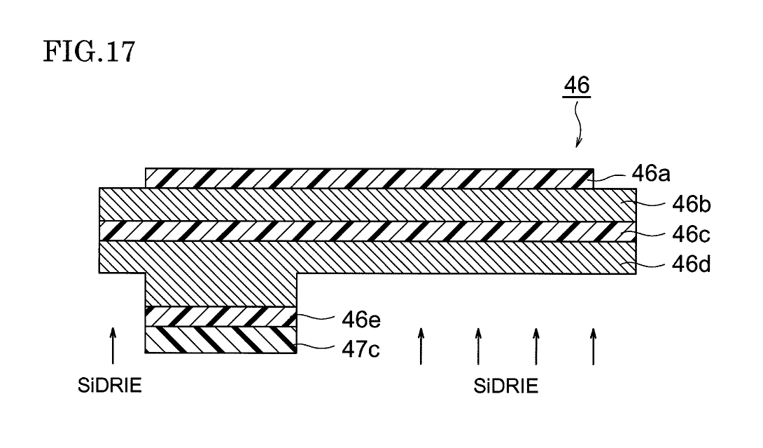

Next, at a ninth step shown in FIG. 17, the support layer 46d is etched from the bottom of the SOI wafer 46 by a DRIE (deep reactive ion etching) method etc. By this etching, the parts of the support layer 46d not protected by the third resist layer 47c are eaten away to a depth of about half of the support layer 46d. Incidentally, for example even the wet etching method may be used to etch the silicon, but it is not possible to process along the crystal orientation <100> by the wet etching method, so this is not suited to the present embodiment.

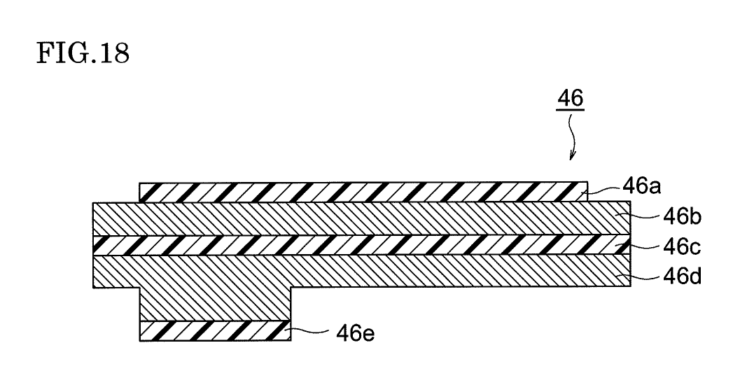

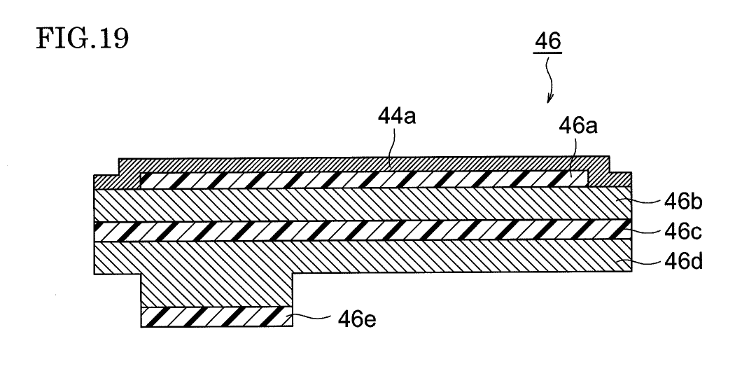

Next, at a 10th step shown in FIG. 18, a similar procedure as the above-mentioned fourth step is used to remove the third resist layer 47c. Next, at an 11th step shown in FIG. 19, a seed layer 44a made of titanium and gold is formed on the entire top surface of the SOI wafer 46. As the specific technique for forming the seed layer 44a, for example, vacuum deposition, sputtering, vapor phase deposition, etc. may be mentioned. This seed layer 44a functions as a power feed layer when forming a later mentioned first interconnect layer 44b.

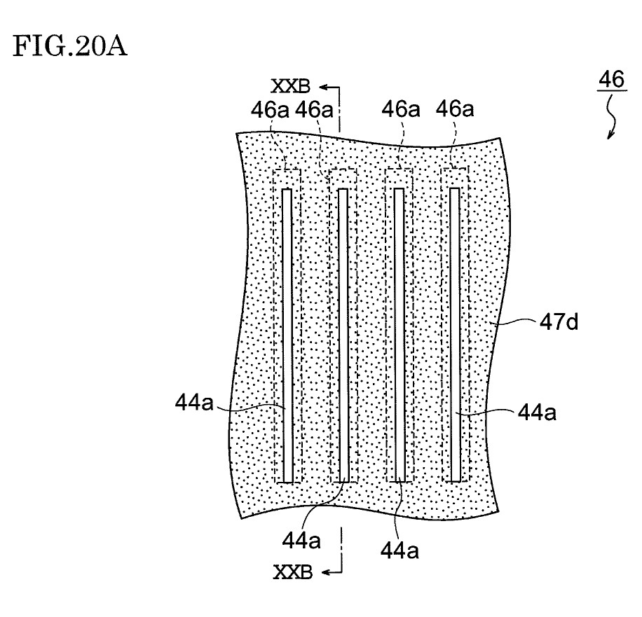

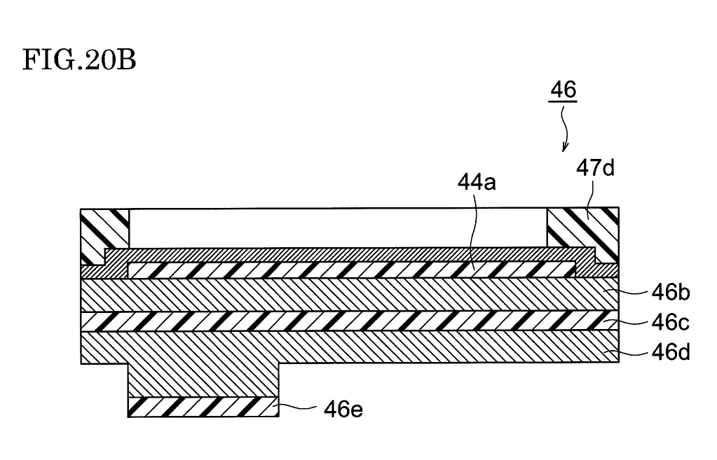

Next, at a 12th step shown in FIG. 20A and FIG. 20B, a similar procedure as in the above-mentioned second step is used to form a fourth resist layer 47d on the surface of the seed layer 44a. This fourth resist layer 47d, as shown in FIG. 20A, is formed on the whole of the seed layer 44a except for the parts where interconnect parts 44 are to be finally formed.

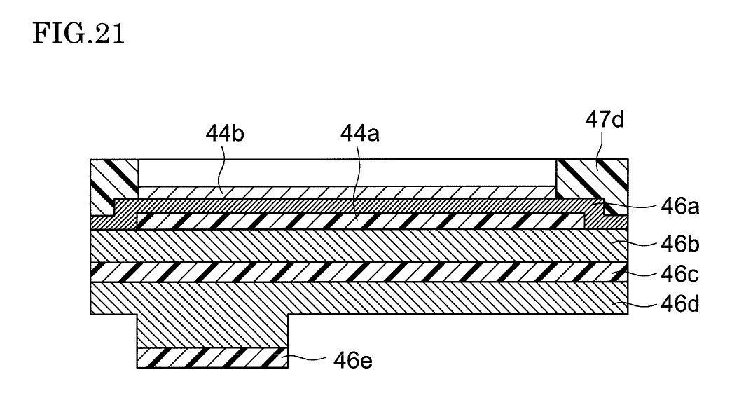

Next, at a 13th step shown in FIG. 21, the parts of the seed layer 44a not covered by the fourth resist layer 47d are plated to form a first interconnect layer 44b.

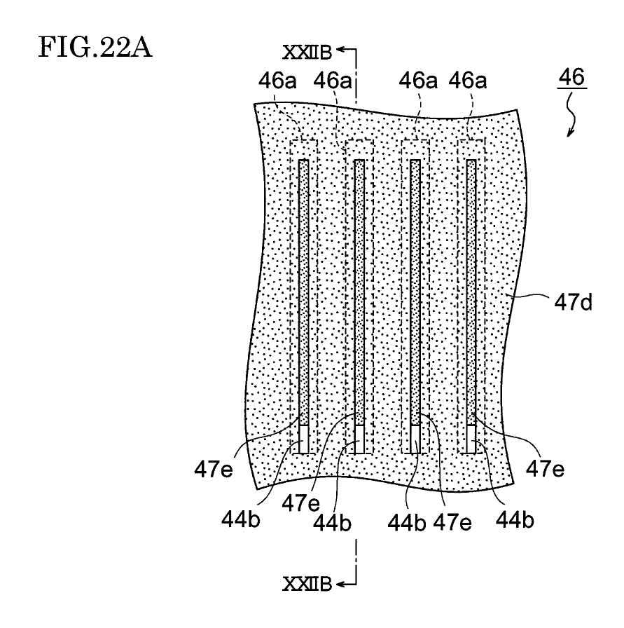

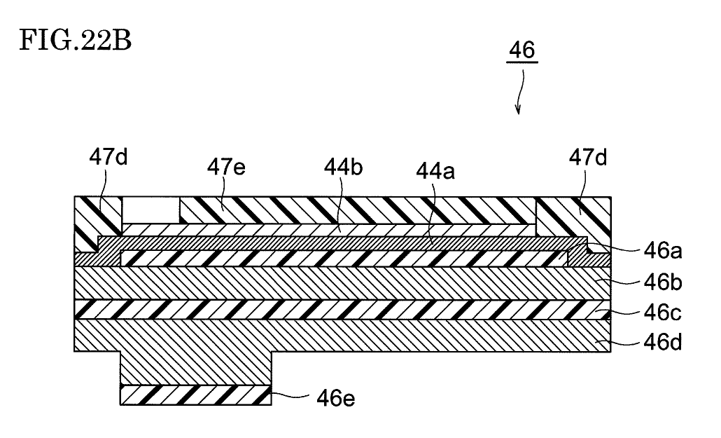

Next, at a 14th step shown in FIG. 22A and FIG. 22B, in the state with the fourth resist layer 47d left on the seed layer 44a, a fifth resist layer 47e is formed. This fifth resist layer 47e, as shown in FIG. 22A, is formed on the whole of the first interconnect layer 44b except for the part of the back end side of the first interconnect layer 44b.

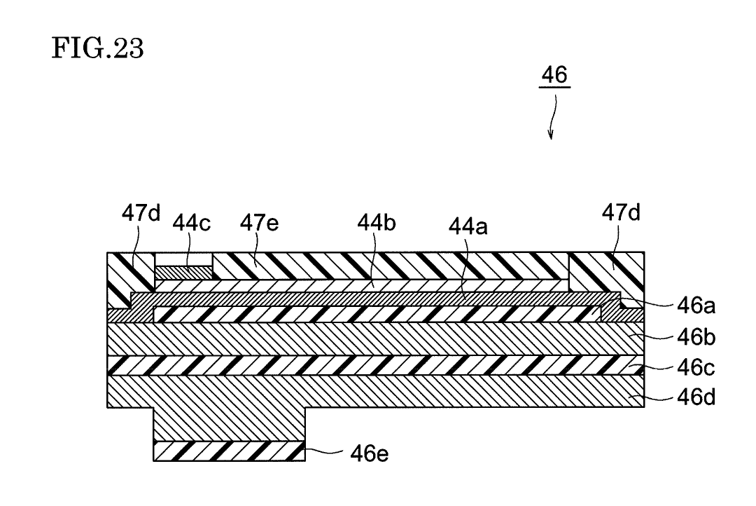

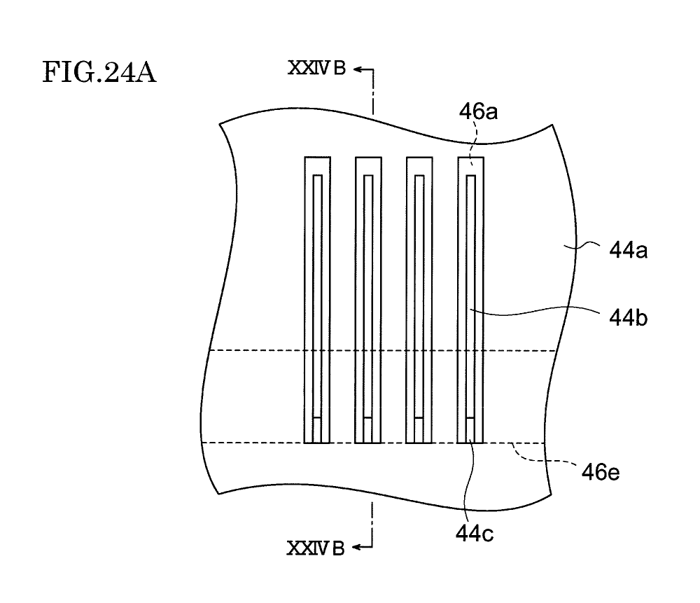

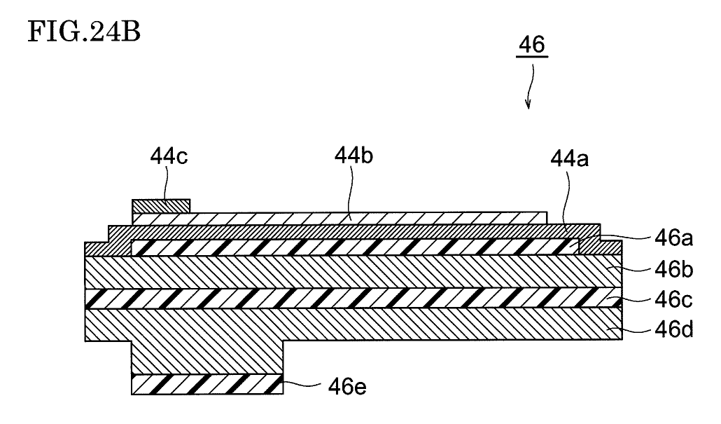

Next, at a 15th step shown in FIG. 23, the parts of the surface of the first interconnect layer 44b not covered by the resist layers 47d and 47e are plated to form the second interconnect layer 44c, while at a 16th step shown in FIG. 24A and FIG. 24B, the resist layers 47d and 47e are removed by a procedure similar to the above-mentioned fourth step.

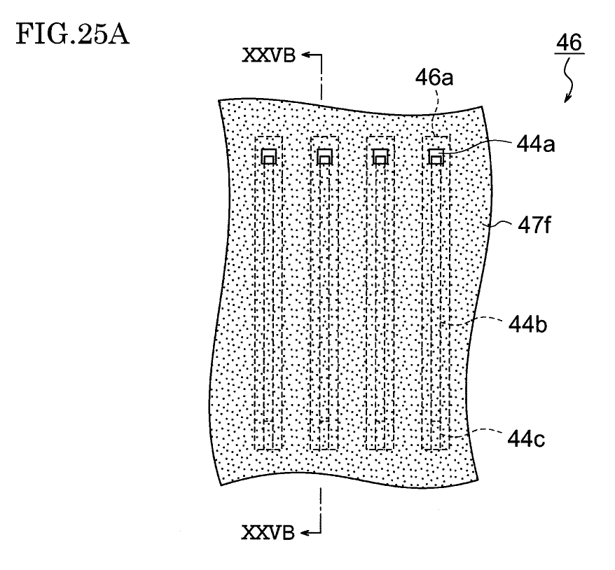

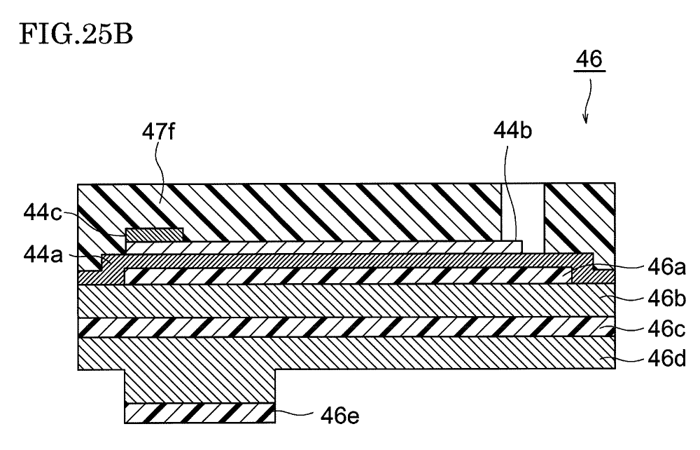

Next, at a 17th step shown in FIG. 25A and FIG. 25B, except for the regions from the front end part of the first interconnect layer 44b to the surface of the seed layer 44a, a sixth resist layer 47f is formed on the entire SOI wafer 46 by a similar procedure as the above-mentioned fourth step. Note that, this sixth resist layer 47f is for forming a first contact layer 45a at a next 17th step, but the first contact layer 45a accounts for the major part of the contact part 45 in the height direction, so at this 16th step, the sixth resist layer 47f is formed sufficiently thick.

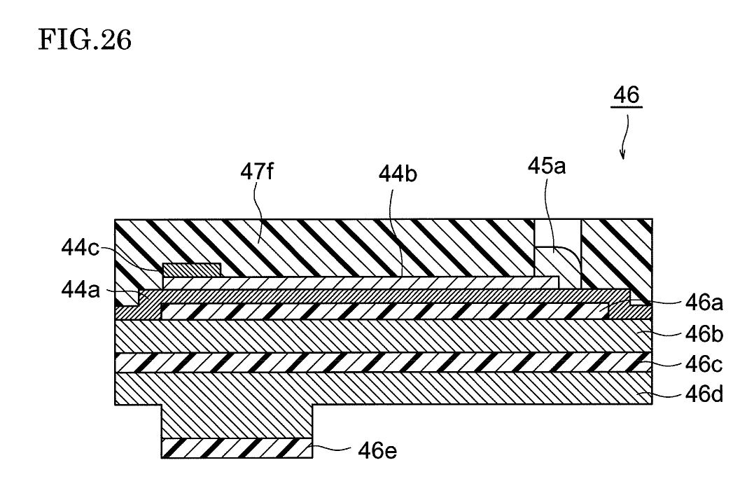

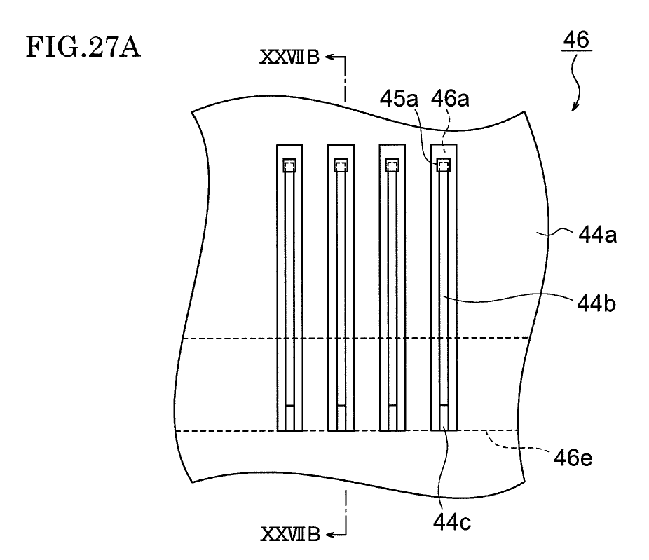

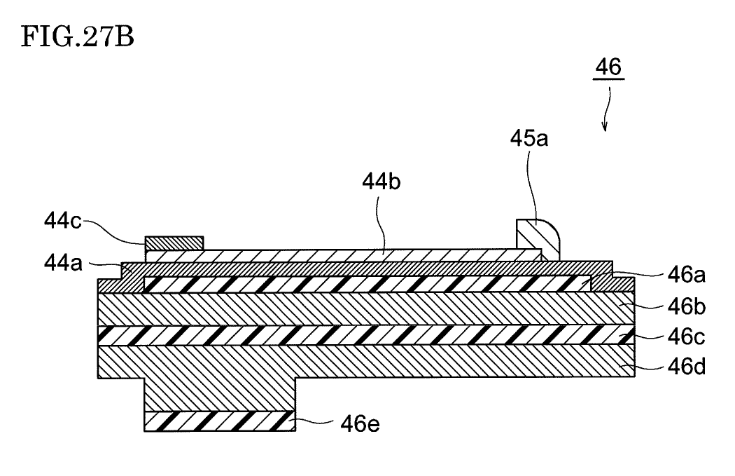

Next, at an 18th step shown in FIG. 26, the parts not covered by the sixth resist layer 47f are plated to form the first contact layer 45a. This Ni plating layer 45a is formed at a step portion between the first interconnect layer 44b and the seed layer 44a, so, as shown in FIG. 26, is formed into a curved shape. Next, at a 19th step shown in FIG. 27A and FIG. 27B, the sixth resist layer 47f is removed by a similar procedure as in the above-mentioned fourth step.

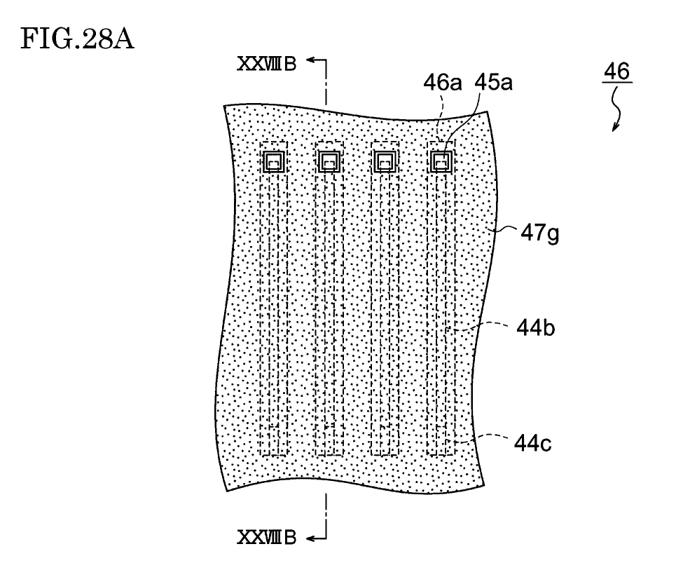

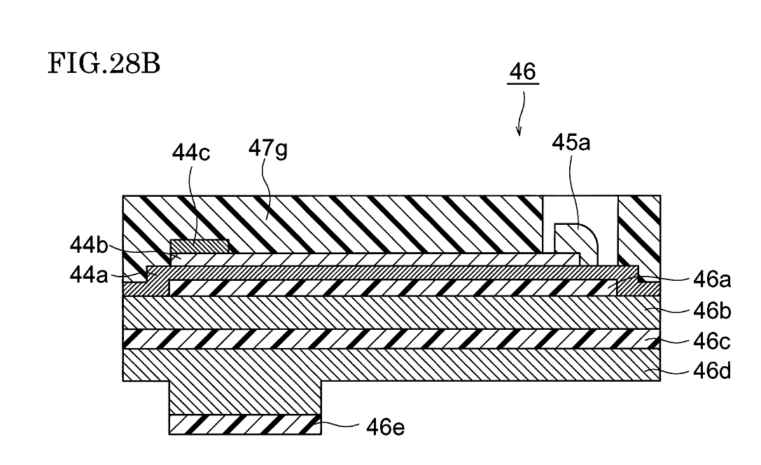

Next, at a 20th step shown in FIG. 28A and FIG. 28B, in a state leaving some space around the first contact layer 45a, a seventh resist layer 47g is formed on the entire surface of the SOI wafer 46 by a procedure similar to the above-mentioned second step.

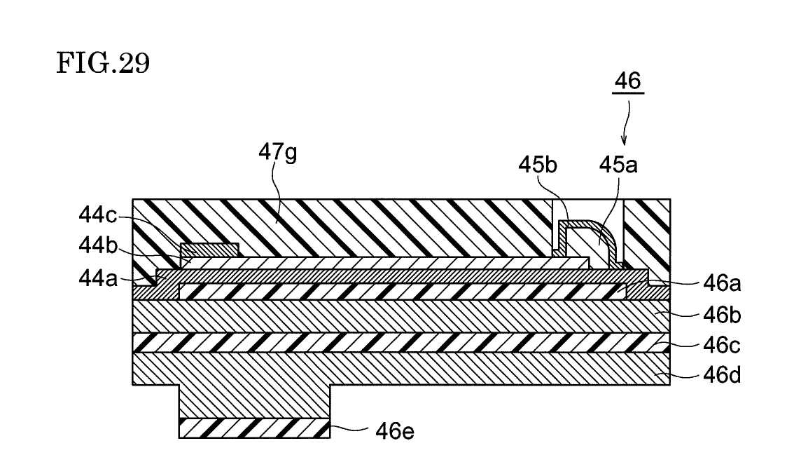

Next, at a 21st step shown in FIG. 29, the parts of the top surface of the SOI wafer 46 not covered by the seventh resist layer 47g are plated with gold to form a second contact layer 45b so as to envelop the first contact layer 45a. Incidentally, this second contact layer 45b is formed for protecting the first contact layer 45a from the plating solution used at the next step when forming a third contact layer 45c by rhodium plating.

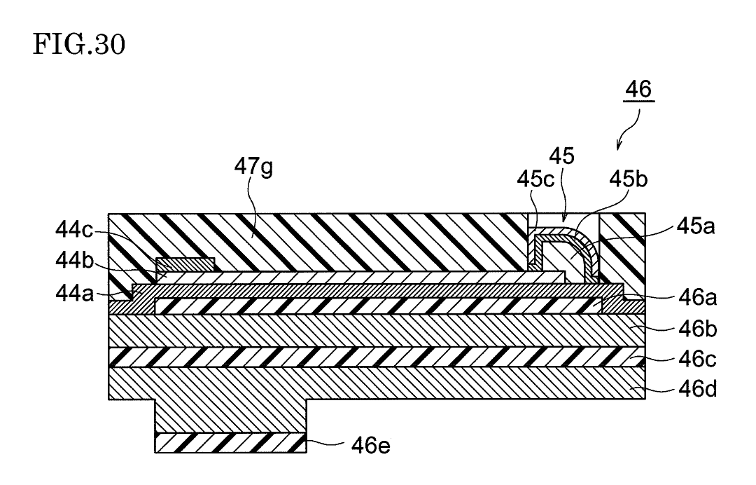

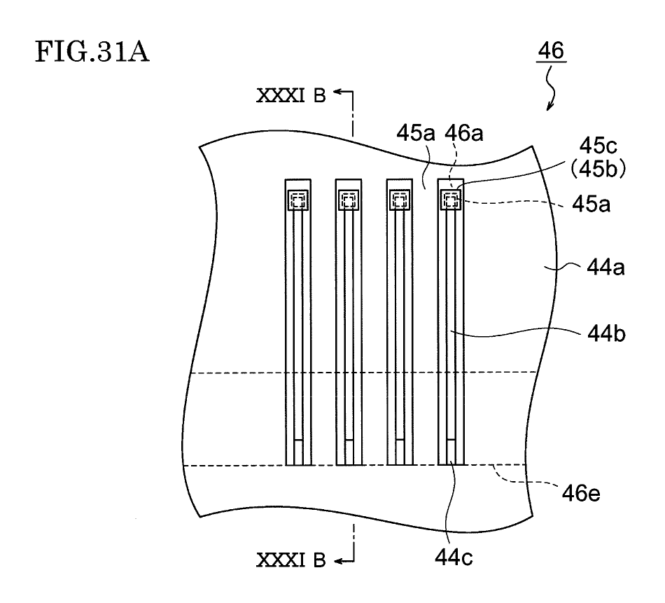

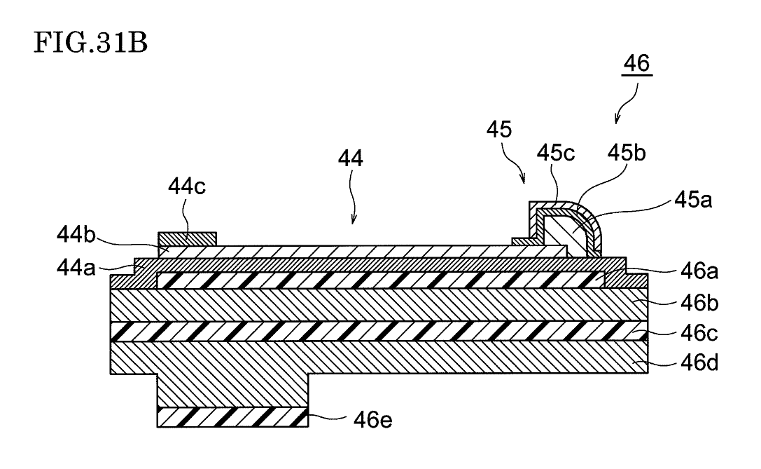

Next, at a 22nd step shown in FIG. 30, in a state leaving the seventh resist layer 47g, the parts of the top surface of the SOI wafer 46 not covered by the seventh resist layer 47g are plated by rhodium to form the third contact layer 45c so as to envelop the second contact layer 45b. Next, at a 23rd step shown in FIG. 31A and FIG. 31B, the seventh resist layer 47g is removed by a procedure similar to the above-mentioned fourth step. The third contact layer 45c has a high hardness (for example, when the third contact layer 45c is made of rhodium, Hv800 to 1000) and is superior in corrosion resistance, so is suitable for the surface of a contact part 45 where long term stable contact resistance and abrasion resistance are demanded.

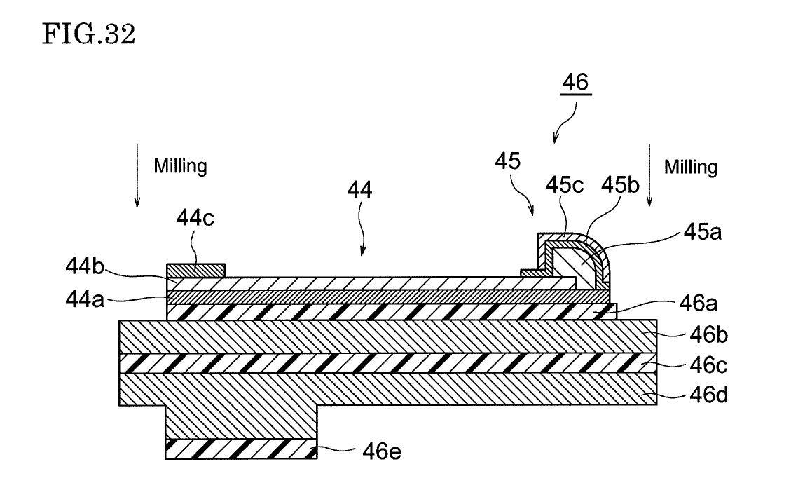

Next, at a 24th step shown in FIG. 32, the exposed parts of the seed layer 44a which functioned as the power feed layer when forming the first interconnect layer 44b by plating is removed by milling. This milling is performed in a vacuum chamber by making argon ions strike the top surface of the SOI wafer 46. At this time, since the seed layer 44a is thinner than the other layers, it is first removed by this milling. Due to this milling, only the parts of the seed layer 44a positioned under an interconnect part 44 and a contact part 45 remain and the other parts are removed.

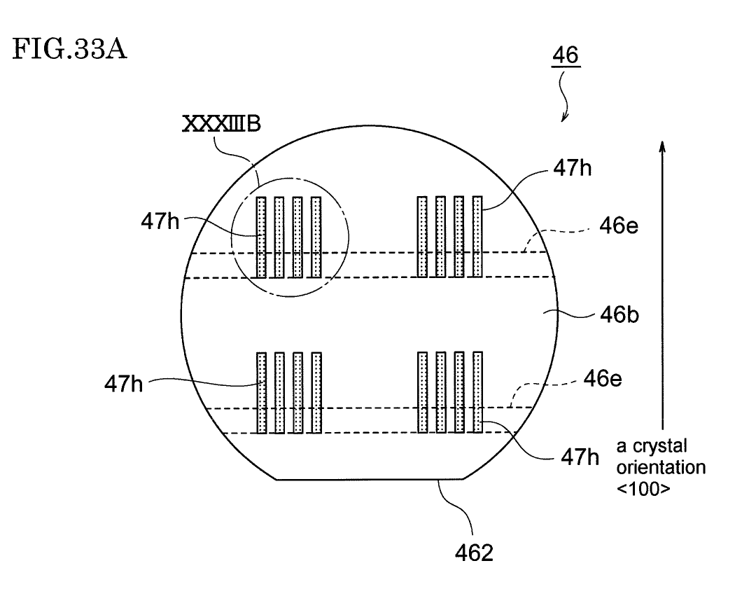

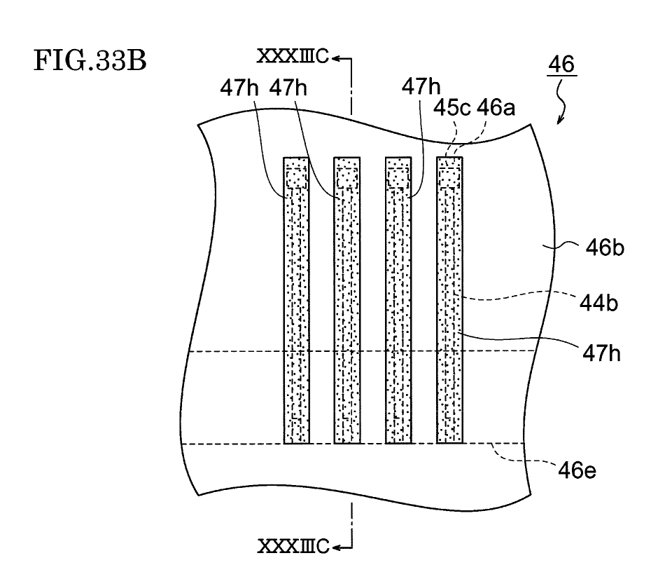

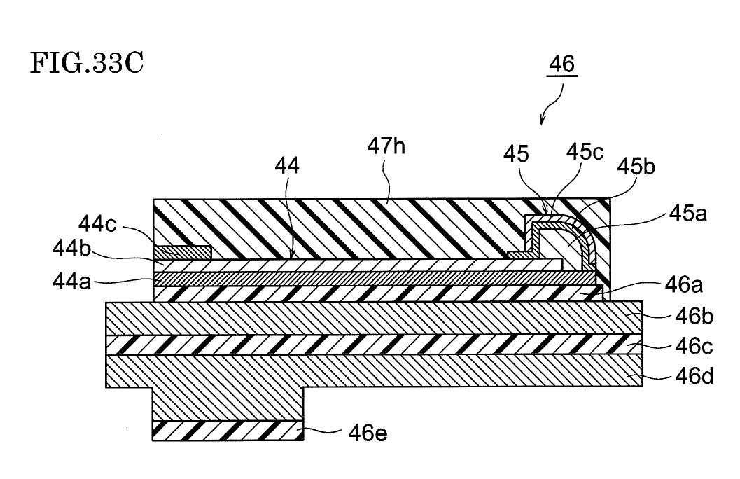

Next, at a 25th step shown in FIG. 33A to FIG. 33C, a plurality of strip shapes of an eighth resist layer 47h are formed on the first SiO₂ layer 46a by a similar procedure as the above-mentioned second step. Note that, in the present embodiment, as shown in FIG. 31A, the longitudinal direction of each strip of the eighth resist layer 47h substantially matches with the crystal orientation <100>.

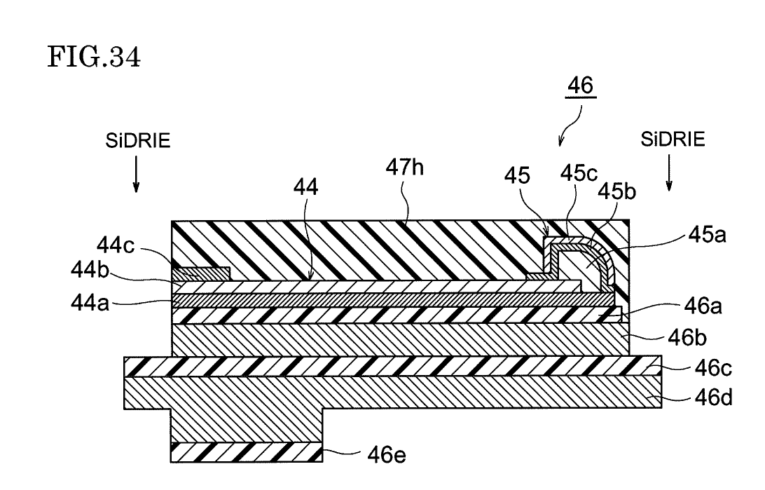

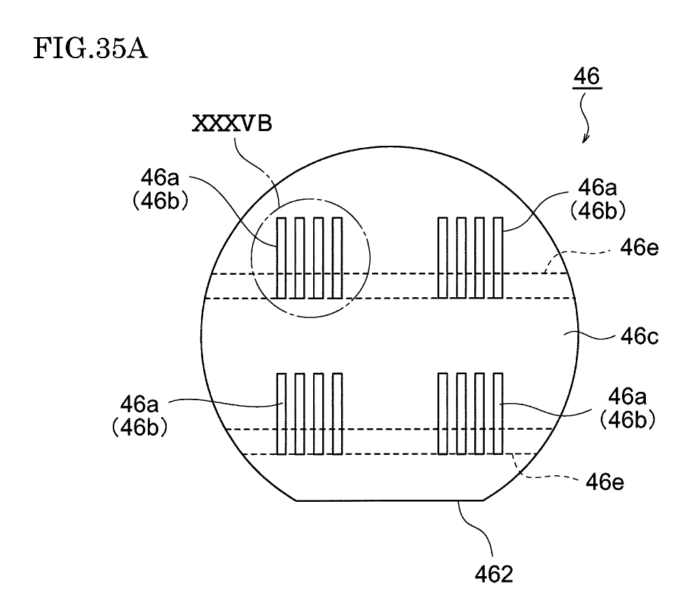

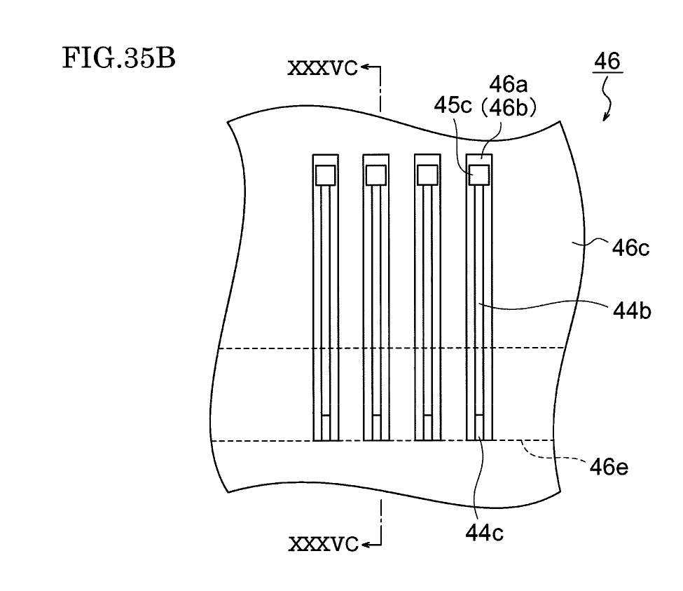

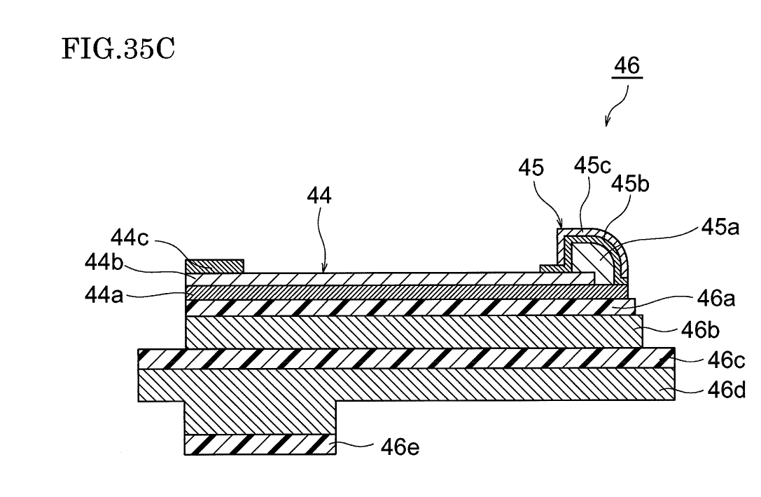

Next, at a 26th step shown in FIG. 34, the active layer (Si layer) 46b is etched from the top of the SOI wafer 46 by a DRIE method. Due to this etching, the active layer 46b is eaten away into a plurality of strip shapes and the active layer 46b becomes a plurality of strip shapes along the crystal orientation <100> (see FIG. 35A). Note that, this DRIE does not eat into the SOI wafer 46 down to the support layer (Si layer) 46d since the BOX layer (SiO₂ layer) 46c functions as an etching stopper.

Further, this etching is performed so that a scallop value of a beam part 42 (roughness of surface relief of side wall surface formed by etching) becomes 100 nm or less. Due to this, when the beam part 42 elastically deforms, it is possible to prevent cracks from occurring starting from rough parts of the side wall surface.

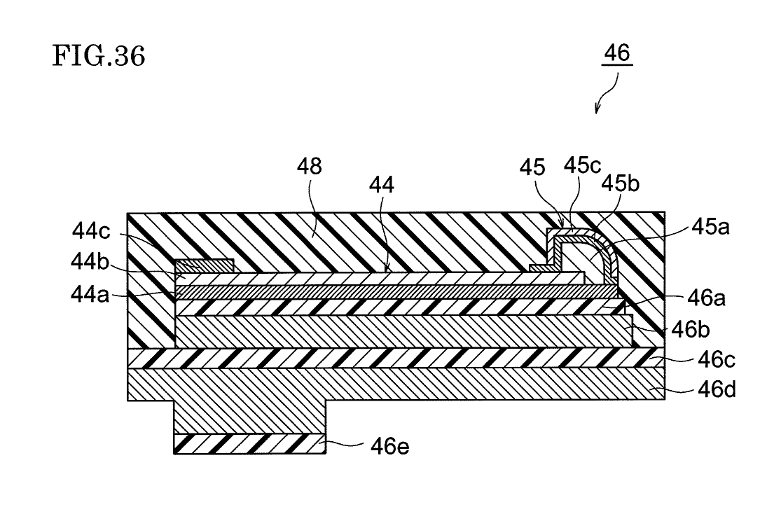

Next, at a 27th step shown in FIG. 35A to FIG. 35C, a similar procedure as the above-mentioned fourth step is used to remove the eighth resist layer 47h. Next, at a 28th step shown in FIG. 36, a polyimide film 48 is formed on the entire top surface of the SOI wafer 46. This polyimide film 48 is formed by coating a polyimide precursor using a spin coater or spray coater etc. on the entire top surface of the SOI wafer 46, then heating to 20° C. or higher or using a catalyst to cause imidization. This polyimide film 48 is formed for preventing coolant from leaking by exposure of a stage of the etching apparatus via through holes and for preventing the stage itself from damaging at the time of etching in the next step and the next step.

Next, at a 29th step shown in FIG. 37, the support layer (Si layer) 46d is etched from the bottom of the SOI wafer 46 by the DRIE method etc. In this etching process, the second SiO₂ layer 46e remaining at the above-mentioned third step functions as a mask material. Note that, this DRIE does not eat into the SOI wafer 46 down to the active layer (Si layer) 46b since the BOX layer (SiO₂ layer) 46c functions as an etching stopper.

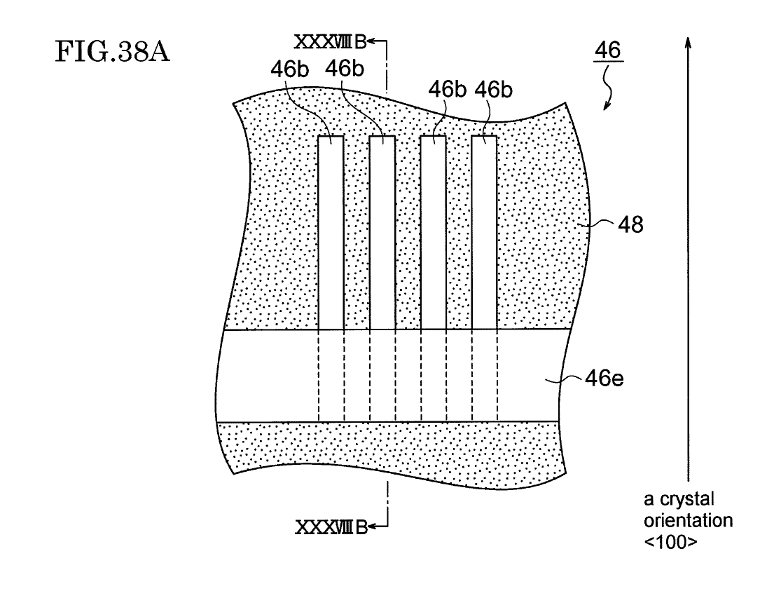

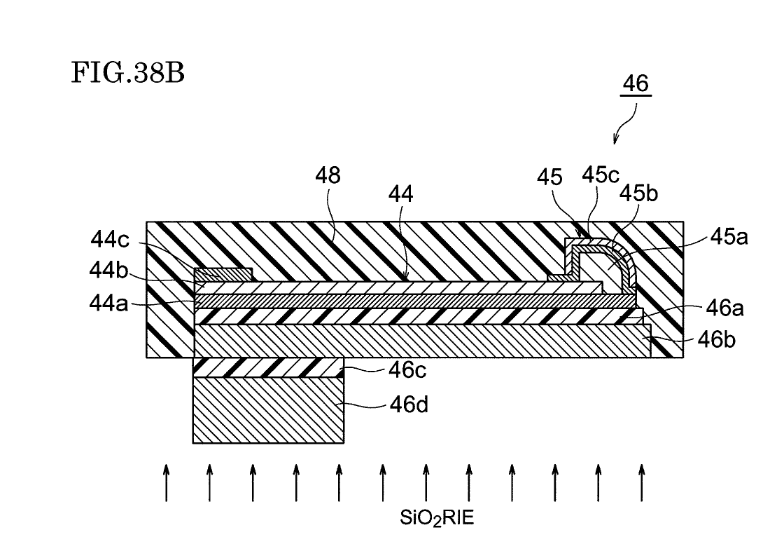

Next, at a 30th step shown in FIG. 38A and FIG. 38B, the two SiO₂ layers 46c and 46e are etched from the bottom of the SOI wafer 46. As specific means for this etching, the RIE method etc. may be mentioned. As shown in FIG. 38A, due to this etching, the beam parts 42 are formed into complete finger shapes. In the present embodiment, the longitudinal direction of each beam part 42 substantially matches with the crystal orientation <100>.

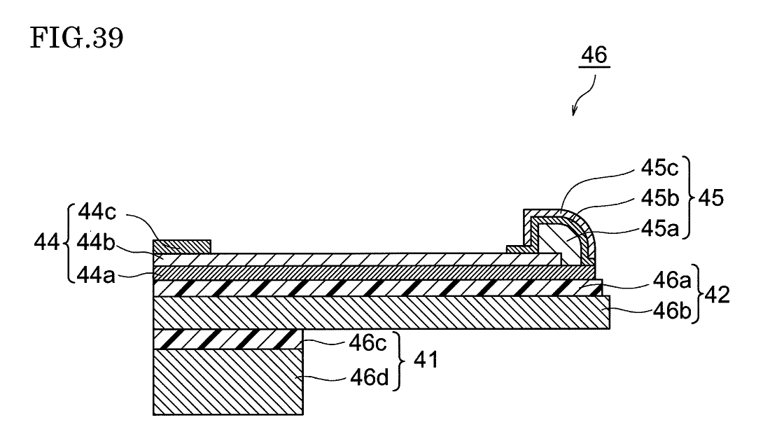

Next, at a 31st step shown in FIG. 39, the unnecessary polyimide film 48 is removed by a strongly alkaline peeling solution. Note that, in the present embodiment, the polyimide precursor directly coated on the wafer 46 is imidized so as to form the polyimide film 48, but the present invention is not particularly limited to this. For example, as the polyimide film 48, it is also possible to use an alkali soluble tackifier to stick a polyimide film on the wafer 46.

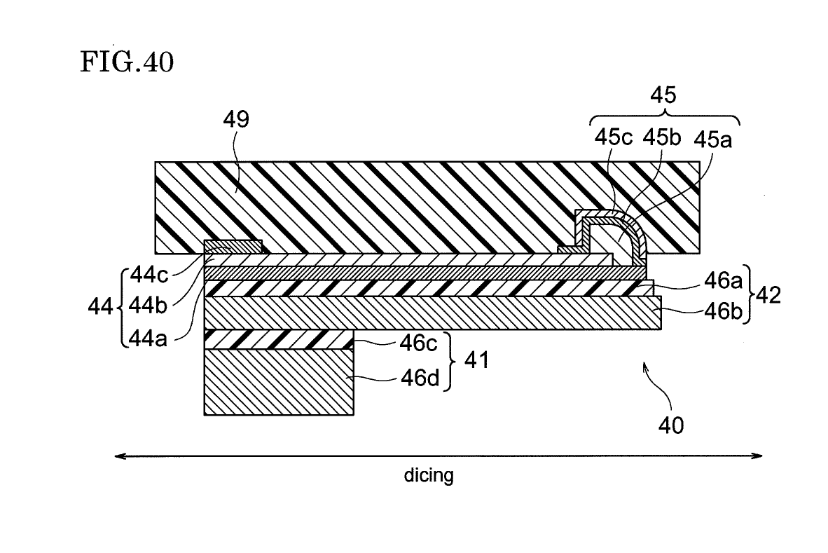

Next, at a 32nd step shown in FIG. 40, a foam peeling tape 49 is adhered on the top surface of the SOI wafer 46, and the SOI wafer 46 is diced along a longitudinal direction of the beam parts 42 in units of predetermined numbers of beam parts 42. Note that, the foam peeling tape 49 is adhered for protecting the beam parts 42 from water pressure at the time of dicing.

This foam peeling tape 49 comprises a base tape including PET on one surface of which a UV foaming tackifier is coated. This foam peeling tape 49 is adhered to the SOI wafer 46 by the UV foaming tackifier in the state not yet irradiated by UV rays, but when irradiated by UV rays, the UV foaming tackifier foams, the tackiness falls, and the tape can be easily peeled off from the SOI wafer 46.

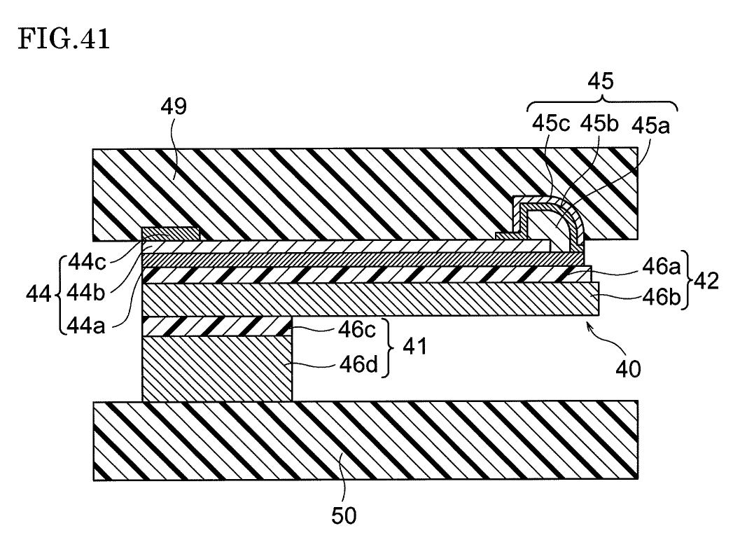

Next, at a 33rd step shown in FIG. 41, in order to enable a diced probe 40 to be handled from above by a pickup system, UV peeling type tape 50 is adhered to the bottom surface of a base part 41.

This UV peeling type tape 50 comprises a base tape including a polyolefin on one surface of which a UV curing type tackifier is coated. This UV peeling type tape 50 is adhered to the bottom surface of a base part 41 by the UV curing type tackifier in the state not yet irradiated by UV rays, but when irradiated by UV rays, the UV curing type tackifier loses its tackiness and the tape can be easily peeled off from the base part 41.

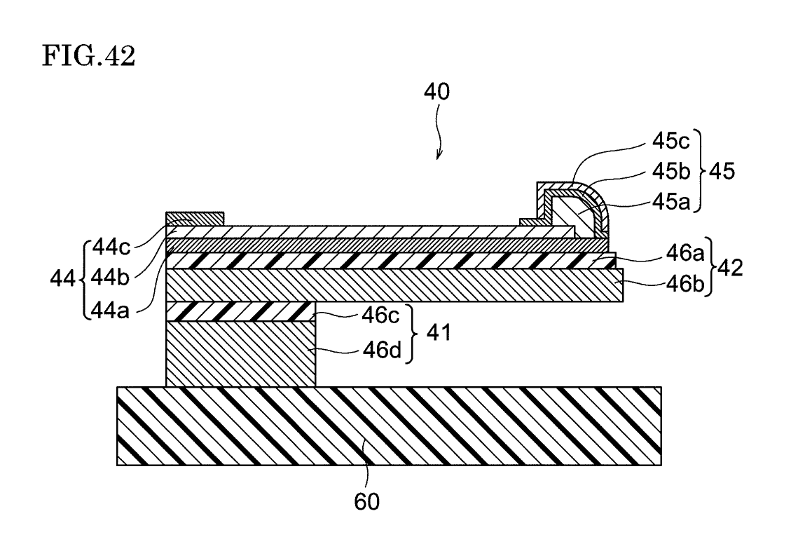

Next, at a 34th step shown in FIG. 42, UV rays are irradiated toward the foam peeling tape 49 to make the UV foaming tackifier of the foam peeling tape 49 foam, and the foam peeling tape 49 is peeled off from a probe 40 to thereby transfer the probe 40 from the foam peeling tape 49 to the UV peeling type tape 50.

Next, while not particularly illustrated, in the state with the pickup system holding a probe 40, UV rays are irradiated toward the UV curing type peeling tape 50 and that tape 50 is peeled from the probe 40. Further, the pickup system places the probe 40 at a predetermined position of the probe board 30 and fixes it by the binder 31d whereby the probe 40 is mounted on the probe board 30.

Note that, the embodiments explained above were described for facilitating understanding of the present invention and were not described for limiting the present invention. Therefore, the elements disclosed in the above embodiments include all design changes and equivalents falling under the technical scope of the present invention.

1. A probe for contacting an input/output terminal of a device under test for establishing an electrical connection between the device under test and a test system when testing the device under test, the probe at least comprising:
a beam part having a Si layer composed of monocrystalline silicon; and
a conductive part provided on one main surface of the beam part along a longitudinal direction of the beam part and to be electrically connected with the input/output terminal of the device under test, wherein
the longitudinal direction of the beam part substantially matches with a crystal orientation <100> of monocrystalline silicon of the Si layer.

2. The probe as set forth in claim 1, further comprising a base part supporting a plurality of the beam parts all together in a cantilever fashion.

3. The probe as set forth in claim 1, wherein the conductive part has:
an interconnect part provided on the one main surface of the beam part along the longitudinal direction; and
a contact part provided at a front end of the interconnect part and contacting the input/output terminal of the device under test.

4. A probe card comprising:
the probe as set forth in claim 2; and
a board to which the base part of the probe is fixed.

5. A method of production of the probe as set forth in claim 1,
comprising:
forming a resist layer on a surface of a silicon wafer; and
etching the silicon wafer to form a beam part.

6. The method of production of the probe as set forth in claim 5 wherein the silicon wafer has a main surface of a surface orientation {100} and is given an orientation flat or notch showing a crystal orientation <100>.

7. The method of production of the probe as set forth in claim 5, wherein
the silicon wafer has a main surface of a surface orientation {100} and is given an orientation flat or notch showing a crystal orientation <110>, and
the method of production of the probe comprises:
forming the resist layer on the surface of the silicon wafer in the state that the silicon wafer is rotated by substantially 45 degree from a usual state so that a longitudinal direction of the beam part is substantially matched with a crystal orientation <100> of the silicon wafer.

8. The method of production of a probe as set forth in claim 5, wherein
the silicon wafer has a main surface of a surface orientation {100} and is given an orientation flat or notch showing a crystal orientation <110>, and
the method of production of the probe comprises:
forming a pattern for forming the resist layer on a mask in the state that the pattern is rotated by substantially 45 degree from a usual state; and
forming the resist layer on the surface of the silicon wafer using the mask so that a longitudinal direction of the beam part is substantially matched with a crystal orientation <100> of the silicon wafer.

9. The method of production of the probe as set forth in claim 5, wherein
the silicon wafer has a main surface of a surface orientation {100} and is given an orientation flat or notch showing a crystal orientation <110>, and
the method of production of the probe comprises:
forming the resist layer on the surface of the silicon wafer in the state that a mask for forming the resist layer is rotated by substantially 45 degree from a usual state so that a longitudinal direction of the beam part is substantially matched with a crystal orientation <100> of the silicon wafer.

10. The method of production of a probe as set forth in claim 5, comprising etching the silicon wafer by using a DRIE (deep reactive ion etching) method.
